(19) United States
(12) Patent Application Publication
(10) Pub. No.: US 2025/0380527 A1
(43) Pub. Date: Dec. 11, 2025

(54) IMAGE SENSOR AND METHOD OF MANUFACTURING THE SAME

(71) Applicant: SAMSUNG ELECTRONICS CO., LTD., Suwon-si (KR)

(72) Inventors: Yongjun KIM, Suwon-si (KR); Seungsik KIM, Suwon-si (KR); Sol YOON, Suwon-si (KR); Kwansik CHO, Suwon-si (KR); Sunhee YUN, Suwon-si (KR); Segyo HAN, Suwon-si (KR)

(73) Assignee: SAMSUNG ELECTRONICS CO., LTD., Suwon-si (KR)

(21) Appl. No.: 19/020,269

(22) Filed: Jan. 14, 2025

(30) Foreign Application Priority Data
Jun. 11, 2024 (KR) 10-2024-0075721

(51) Int. Cl. H10F 39/00; H10F 39/18

(52) U.S. Cl. CPC H10F 39/811; H10F 39/014; H10F 39/182; H10F 39/807

(57) ABSTRACT

An image sensor includes a substrate, a pixel region defined by an isolation structure in the substrate, a first floating diffusion region on the pixel region, a source follower gate electrode on the substrate, and a first buried line on the isolation structure. The first buried line electrically connects the first floating diffusion region to the source follower gate electrode, and the first buried line is disposed in the substrate. The first buried line includes a first line portion extending from the first floating diffusion region in a first direction, and a second line portion extending from the source follower gate electrode in a second direction that intersects the first direction.

### CROSS-REFERENCE TO RELATED APPLICATION

This U.S. non-provisional patent application claims priority under 35 U.S.C. § 119 of Korean Patent Application No. 10-2024-0075721, filed on Jun. 11, 2024, the entire contents of which being hereby incorporated by reference.

### BACKGROUND

The present disclosure herein relates to an image sensor and method of manufacturing an image sensor, and more particularly, to an image sensor having more improved electrical and optical characteristics.

An image sensor converts an optical image into an electrical signal. Recently, with the development of the computer industry and communication industry, a demand for an image sensor with improved performance has increased in various fields such as a digital camera, a camcorder, a personal communication system (PCS), a game console, a security camera, and a medical micro camera, etc.

There are different types of image sensors such as a charge coupled device (CCD) and a CMOS image sensor. The CMOS image sensor is simply driven and makes it possible to provide a small-size product since a signal processing circuit is integrated on a single chip. The CMOS image sensor also has relatively low power consumption, and thus may be easily applied to a product with limited battery capacity. In addition, CMOS process technology may be compatibly used for the CMOS image sensor, thereby reducing manufacturing cost. Thus, the use of the CMOS image sensor is rapidly increasing since the CMOS image sensor may provide high resolution with the development of technology.

### SUMMARY

It is an aspect to provide an image sensor having more improved electrical and optical characteristics.

It is another aspect to provide a method for manufacturing an image sensor having more improved electrical and optical characteristics.

Aspects are not limited to the aspects mentioned above, and other aspects that are not mentioned may be clearly understood by those skilled in the art from the detailed description of various embodiments below.

According to an aspect of one or more embodiments, there is provided an image sensor comprising a substrate; a pixel region defined by an isolation structure in the substrate; a first floating diffusion region on the pixel region; a source follower gate electrode on the substrate; and a first buried line on the isolation structure. The first buried line electrically connects the first floating diffusion region to the source follower gate electrode and the first buried line is disposed in the substrate. The first buried line includes a first line portion extending from the first floating diffusion region in a first direction, and a second line portion extending from the source follower gate electrode in a second direction that intersects the first direction.

According to another aspect of one or more embodiments, there is provided an image sensor comprising a substrate; a pixel region defined by an isolation structure in the substrate; a first floating diffusion region on the pixel region; a source follower gate electrode on the substrate; a first buried line on the isolation structure; and a first source follower contact on the source follower gate electrode, wherein the first buried line electrically connects the first floating diffusion region to the source follower gate electrode, and the first source follower contact is in contact with each of the source follower gate electrode and the first buried line.

According to yet another aspect of one or more embodiments, there is provided an image sensor comprising a substrate including a first pixel group and a second pixel group adjacent to the first pixel group in a first direction, the first pixel group and the second pixel group each including a 2×2 array of pixels; an isolation structure that is disposed in the substrate and that isolates the first pixel group, the second pixel group and the pixels; a first floating diffusion region located at a center of the first pixel group; a second floating diffusion region located at a center of the second pixel group; a source follower gate electrode disposed on the substrate in one of the pixels of the first pixel group; a photoelectric conversion part disposed in the substrate in each of the pixels; a first transfer gate electrode adjacent to the first floating diffusion region in each of the pixels of the first pixel group; a second transfer gate electrode adjacent to the second floating diffusion region in each of the pixels of the second pixel group; a first buried line disposed in the substrate and electrically connecting the first floating diffusion region to the source follower gate electrode; and a first source follower contact on the source follower gate electrode, wherein the first floating diffusion region is electrically connected to the first source follower contact through the first buried line.

According to yet another aspect of one or more embodiments, there is provided a method for manufacturing an image sensor, the method comprising forming a pixel region defined by an isolation structure on a substrate; forming a first floating diffusion region and a first buried line in the substrate; forming, on the pixel region, a source follower gate electrode which electrically connects the first floating diffusion region to the source follower gate electrode; and forming a first source follower contact on the source follower gate electrode. The forming the first floating diffusion region and the first buried line includes forming a first etched portion by etching an upper portion of the substrate and an upper portion of the isolation structure, and filling the first etched portion with a semiconductor material.

### BRIEF DESCRIPTION OF THE FIGURES

The above and other aspects are further described with reference to the accompanying drawings, which are included to provide a further understanding and are incorporated in and constitute a part of this specification, and in which:

FIG. 1 is a schematic plan view of an image sensor according to some embodiments;

FIG. 2 is a plan view illustrating an image sensor of FIG. 1 added with lines;

FIG. 3 is a partial perspective view of an image sensor of FIG. 2;

FIG. 4 is a circuit diagram of an image sensor of FIG. 2;

FIG. 5 is a cross-sectional view taken along line A-A′ of FIG. 2, according to some embodiments;

FIG. 6 is a cross-sectional view taken along line B-B′ of FIG. 2, according to some embodiments;

FIG. 7A is an enlarged view of region M in the cross-section view of FIG. 6, according to some embodiments;

FIG. 7B is an enlarged view of region M in the cross-section view of FIG. 6, according to some embodiments;

FIGS. 8A to 16B are diagrams for describing a method for manufacturing an image sensor according to some embodiments;

FIG. 17 is a plan view of an image sensor according to some embodiments;

FIGS. 18 and 19 are plan views of an image sensor according to some embodiments; and

FIGS. 20 and 21 are cross-sectional views of an image sensor according to some embodiments.

### DETAILED DESCRIPTION

Hereinafter, various embodiments will be described in more detail with reference to the accompanying drawings in order to describe the various embodiments in more detail. Herein, the terms indicating order, such as “first”, “second”, etc., are used to distinguish elements having same/similar functions, and ordinal numbers may be interchanged according to the order in which the terms are mentioned. As used in this specification, a phrase of a form: “at least one of A, B, or C” includes within its scope “only A”, “only B”, “only C”, “A and B”, “A and C”, “B and C” and “A, B, and C.”

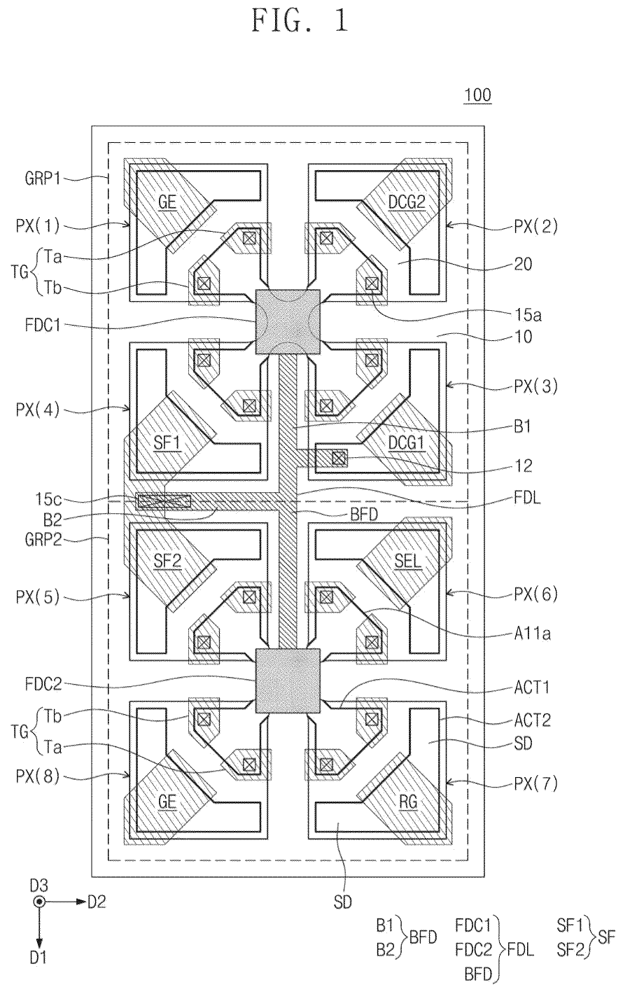

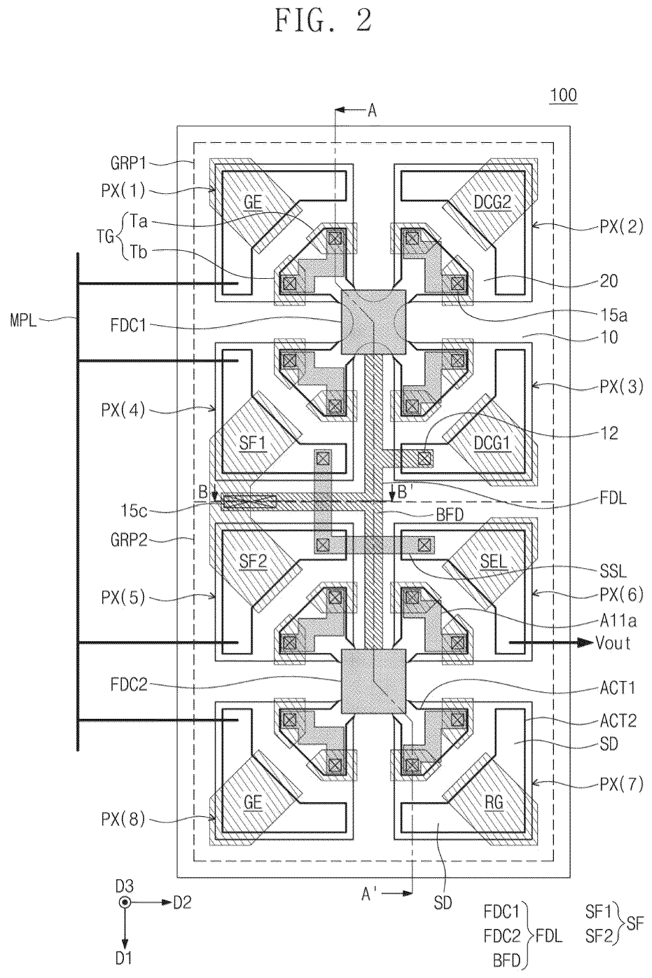

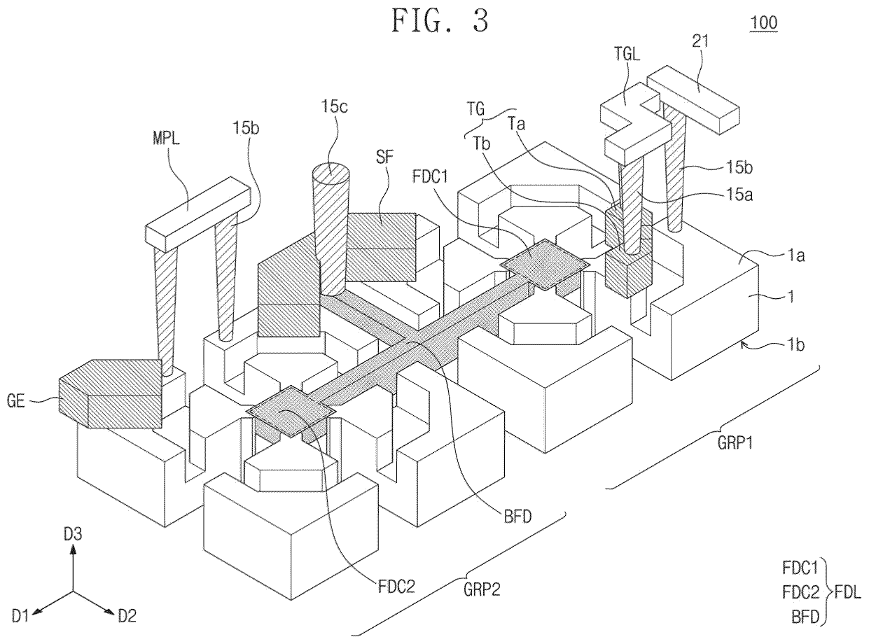

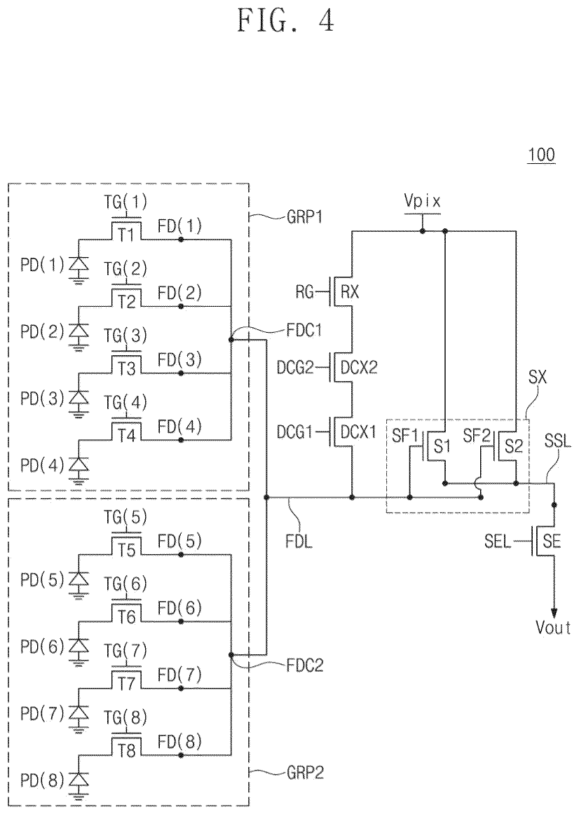

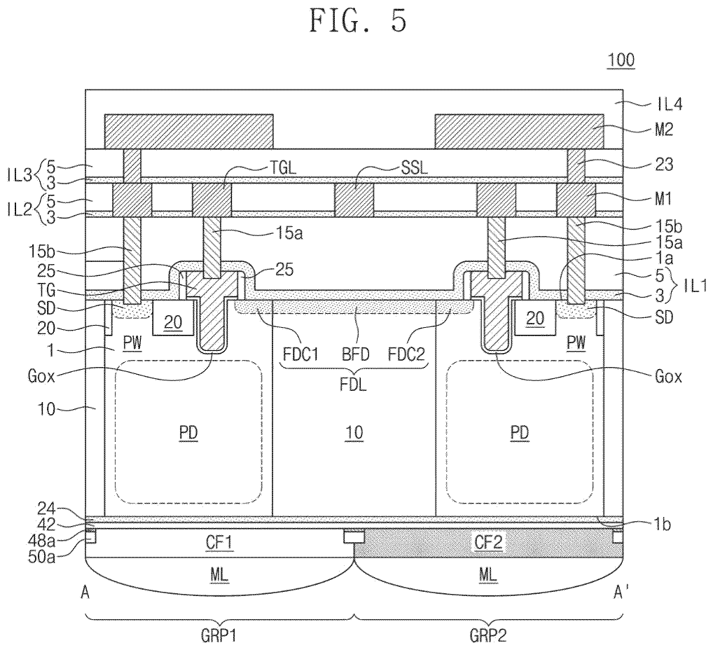

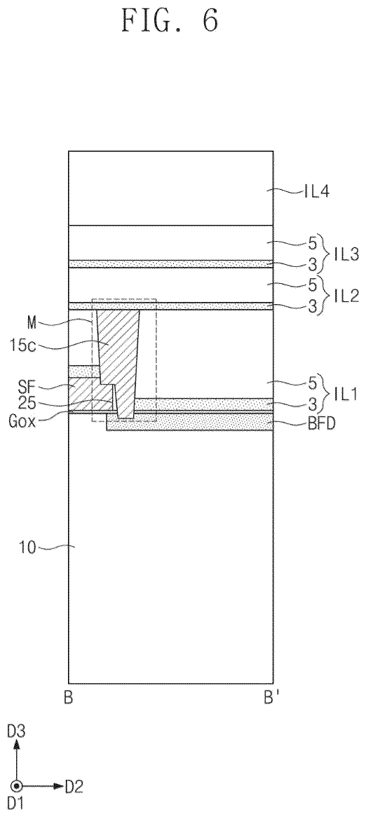

FIG. 1 is a schematic plan view of an image sensor according to some embodiments. FIG. 2 is a plan view illustrating the image sensor of FIG. 1 added with lines. FIG. 3 is a partial perspective view of an image sensor of FIG. 2. FIG. 4 is a circuit diagram of the image sensor of FIG. 2. FIG. 5 is a cross-sectional view taken along line A-A′ of FIG. 2, according to some embodiments. FIG. 6 is a cross-sectional view taken along line B-B′ of FIG. 2 according to some embodiments.

Referring to FIGS. 1 to 6, an image sensor 100 is provided with a substrate 1. The substrate 1 may include a plurality of pixels PX arranged two-dimensionally along a first direction D1 and a second direction D2 intersecting each other. FIG. 1 illustrates one pixel PX as an example. The substrate 1 may include a first face la and a second face 1b opposing each other (see FIG. 3). Light may be incident into the substrate 1 through the second face 1b. The substrate 1 may be a silicon on insulator (SOI) substrate, an epitaxial layer, or a single-crystal wafer including silicon and/or germanium. A well region PW may be formed in the substrate 1 (see FIG. 5). The well region PW may be doped with a first-conductive type impurity. In some embodiments, the first conductive type may be, for example, a P type. In some embodiments, the first-conductive type impurity may be, for example, boron. However, embodiments are not limited thereto and, in some embodiments, other materials may be used for the first-conductive type impurity. In some embodiments, the first conductivity type may be an N type.

The substrate 1 may include an isolation structure 10 that isolates photoelectric conversion parts PD from each other and that defines the photoelectric conversion parts PD. The isolation structure 10 may be disposed in the substrate 1. The isolation structure 10 may have a mesh shape in a plan view. The isolation structure 10 may include an isolation conductive pattern disposed therein, and an isolation insulating pattern between the isolation conductive pattern and the substrate 1. The isolation structure 10 may penetrate the substrate 1. The isolation structures 10 have been omitted in FIG. 3 for ease of illustration.

The pixels PX constituting a 2×2 array may be arranged in a plurality of pixel groups. The plurality of pixel groups may be arranged along the first direction D1 and the second direction D2. Referring to FIGS. 1 and 2, the pixel groups may include a first pixel group GRP1 and a second pixel group GRP2 disposed along the first direction D1. The first pixel group GRP1 may include a first pixel PX(1), a second pixel PX(2), a third pixel PX(3), and a fourth pixel PX(4) arranged clockwise. The second pixel group GRP2 may include a fifth pixel PX(5), a sixth pixel PX(6), a seventh pixel PX(7), and an eighth pixel PX(8) arranged clockwise. The isolation structure 10 may isolate the pixel groups GRP1 and GRP2 from each other. The isolation structure 10 may isolate the pixels PX from each other in each of the pixel groups GRP1 and GRP2. The isolation structure 10 may be omitted at a center of each of the pixel groups GRP1 and GRP2.

A photoelectric conversion part PD may be disposed in the substrate 1 in each of the pixels PX. The photoelectric conversion part PD may be doped with an impurity of a second conductive type opposite to the first conductive type. In some embodiments, the second conductive type may be, for example, an N type. In some embodiments, the second-conductive type impurity may be, for example, phosphorus or arsenic. However, embodiments are not limited thereto and, in some embodiments, the second-conductivity type impurity may be a P type. The photoelectric conversion part PD which is an N-type impurity region may form a PN junction with the well region PW which is a P-type impurity region to constitute a photodiode. An electron-hole pair may be generated when light is incident to the PN junction. Electrons may be moved to the photoelectric conversion part PD which is an N-type impurity region and may be accumulated.

The substrate 1 may include a device isolation structure 20 that is disposed adjacent to the first face la in the substrate 1 in each of the pixels PX and that defines a first active region ACT1 and a second active region ACT2. The device isolation structure 20 may be formed in a shallow trench isolation (STI) method. The device isolation structure 20 may be formed as a single-layer or multi-layer structure of at least one of a silicon oxide film, a silicon nitride film, or a silicon oxynitride film. In some embodiments, the device isolation structure 20 may be formed by doping a portion of the substrate 1 with a first-conductive type impurity that is the same as an impurity with which the substrate 1 is doped and the device isolation structure 20 may have a higher doping concentration than the remaining portion of the substrate 1. In some embodiments, the isolation structure 10 may penetrate the device isolation structure 20. The device isolation structure 20 may be omitted at the center of each of the first and second pixel groups GRP1 and GRP2. The device isolation structures 20 have been omitted in FIG. 3 for ease of illustration.

A plurality of transfer transistors may be respectively arranged on the first active regions ACT1 of the first to eighth pixels PX(1) to PX(8). For example, the plurality of transfer transistors may include a first transfer transistor T1, a second transfer transistor T2, a third transfer transistor T3, a fourth transfer transistor T4, a fifth transfer transistor T5, a sixth transfer transistor T6, a seventh transfer transistor T7, and an eighth transfer transistor T8. One end of a transfer transistor (one of the first to eighth transfer transistors T1 to T8) may be connected to the photoelectric conversion part PD in each pixel PX. Each transfer transistor (one of the first to eighth transfer transistors T1 to T8) may include a floating diffusion region FD disposed in the substrate 1 and a transfer gate electrode TG disposed next to the floating diffusion region FD. The transfer gate electrodes TG of the first to eight pixels PX(1) to PX(8) may be referred to as a first transfer gate electrode TG(1), a second transfer gate electrode TG(2), a third transfer gate electrode TG(3), a fourth transfer gate electrode TG(4), a fifth transfer gate electrode TG(5), a sixth transfer gate electrode TG(6), a seventh transfer gate electrode TG(7), and an eighth transfer gate electrode TG(8). One transfer gate electrode TG may include a first sub transfer gate Ta and a second sub transfer gate Tb separated from each other. The floating diffusion region FD may be doped with an impurity of the second conductive type.

The floating diffusion regions FD of the first to fourth pixels PX(1) to PX(4) may be connected to each other and constitute a first common floating diffusion region FDC1 at the center of the first pixel group GRP1. The floating diffusion regions FD of the fifth to eighth pixels PX(5) to PX(8) may be connected to each other and constitute a second common floating diffusion region FDC2 at the center of the second pixel group GRP2. The first to fourth pixels PX(1) to PX(4) may share the first common floating diffusion region FDC1. The fifth to eighth pixels PX(5) to PX(8) may share the second common floating diffusion region FDC2.

The first common floating diffusion region FDC1 and the second common floating diffusion region FDC2 may be doped with the same second-conductive type impurity as the floating diffusion regions FD at the same concentration as the concentrations of the floating diffusion regions FD (see FIG. 4). A portion of the floating diffusion regions FD are referred to as the first and second common floating diffusion regions FDC1 and FDC2 for clarity of description, but the terms first and second common floating diffusion regions FDC1 and FDC2 and floating diffusion regions FD may be substantially the same and, in some embodiments, may have no boundary therebetween, and may be used interchangeably. The first and second common floating diffusion regions FDC1 and FDC2 may be also referred to as the floating diffusion regions FD.

A gate electrode of a driving transistor or a gate electrode of a dummy transistor may be disposed on each of the second active regions ACT2 of the first to eighth pixels PX(1) to PX(8). The second active regions ACT2 may have an “L” shape in a plan view.

Specifically, referring to FIG. 1, a gate electrode GE of a driving transistor may be disposed at the center of the second active region ACT2 of the first pixel PX(1) of the first pixel group GRP1. This structural configuration is because a gate electrode of a transistor of a second sub-chip CH2 may be located instead of dummy gate electrodes since ground regions to be described later are disposed on a first buried line. Source/drain regions SD doped with an impurity of the second conductive type may be disposed in the substrate 1 on two sides of the gate electrode GE.

In some embodiments, a first dummy gate electrode may be disposed at the center of the second active region ACT2 of the first pixel PX(1) of the first pixel group GRP1. A first ground region may be disposed in the substrate 1 on one side of the first dummy gate electrode. The first ground region may be doped with an impurity of the first conductive type at a higher concentration than an impurity of the well region PW of the substrate 1. The first ground region may be in contact with the well region PW of the first pixel group GRP1. A source/drain region SD doped with an impurity of the second conductive type may be disposed in the substrate 1 on another side of the first dummy gate electrode DM1.

A second dual conversion gate electrode DCG2 may be disposed at the center of the second active region ACT2 of the second pixel PX(2) of the first pixel group GRP1. Source/drain regions SD doped with an impurity of the second conductive type may be disposed in the substrate 1 on two sides of the second dual conversion gate electrode DCG2 and may constitute a second dual conversion transistor DCX2 of FIG. 4 together with the second dual conversion gate electrode DCG2.

A first dual conversion gate electrode DCG1 may be disposed at the center of the second active region ACT2 of the third pixel PX(3) of the first pixel group GRP1. Source/drain regions SD doped with an impurity of the second conductive type may be disposed in the substrate 1 on two sides of the first dual conversion gate electrode DCG1 and may constitute a first dual conversion transistor DCX1 of FIG. 4 together with the first dual conversion gate electrode DCG1.

A first source follower gate electrode SF1 may be disposed at the center of the second active region ACT2 of the fourth pixel PX(4) of the first pixel group GRP1. Source/drain regions SD doped with an impurity of the second conductive type may be disposed in the substrate 1 on two sides of the first source follower gate electrode SF1 and may constitute a first source follower transistor S1 of FIG. 4 together with the first source follower gate electrode SF1.

The fifth pixel PX(5) of the second pixel group GRP2 is located next to the fourth pixel PX(4) of the first pixel group GRP1 in the first direction D1. A second source follower gate electrode SF2 may be disposed at the center of the second active region ACT2 of the fifth pixel PX(5) of the second pixel group GRP2. Source/drain regions SD doped with an impurity of the second conductive type may be disposed in the substrate 1 on two sides of the second source follower gate electrode SF2 and may constitute a second source follower transistor S2 of FIG. 4 together with the second source follower gate electrode SF2. In the embodiment illustrated with respect to FIGS. 1-6, the second source follower gate electrode SF2 and the first source follower gate electrode SF1 may be integrally connected to each other and may constitute one source follower gate electrode SF. That is, the source follower gate electrode SF may traverse the isolation structure 10 between the first pixel group GRP1 and the second pixel group GRP2.

A selection gate electrode SEL may be disposed at the center of the second active region ACT2 of the sixth pixel PX(6) of the second pixel group GRP2. Source/drain regions SD doped with an impurity of the second conductive type may be disposed in the substrate 1 on two sides of the selection gate electrode SEL and may constitute a selection transistor SE of FIG. 4 together with the selection gate electrode SEL.

A reset gate electrode RG may be disposed at the center of the second active region ACT2 of the seventh pixel PX(7) of the second pixel group GRP2. Source/drain regions SD doped with an impurity of the second conductive type may be disposed in the substrate 1 on two sides of the reset gate electrode RG and may constitute a reset transistor RX of FIG. 4 together with the reset gate electrode RG.

A gate electrode GE of a driving transistor may be disposed at the center of the second active region ACT2 of the eighth pixel PX(8) of the second pixel group GRP2. This structural configuration is because a gate electrode of a transistor of a second sub-chip CH2 may be located instead of dummy gate electrodes since ground regions to be described later are disposed on a first buried line. Source/drain regions SD doped with an impurity of the second conductive type may be disposed in the substrate 1 on two sides of the gate electrode GE.

In some embodiments, a second dummy gate electrode may be disposed at the center of the second active region ACT2 of the eighth pixel PX(8) of the second pixel group GRP2. A ground region may be disposed in the substrate 1 on one side of the second dummy gate electrode. The ground region may be doped with an impurity of the first conductive type at a higher concentration than the well region PW of the substrate 1. The ground region may be in contact with the well region PW of the second pixel group GRP2. A source/drain region SD may be disposed in the substrate 1 on another side of the second dummy gate electrode DM2.

Referring to FIGS. 2 and 3, a transfer gate connection line TGL may connect the first sub transfer gate Ta and the second sub transfer gate Tb adjacent to each other on one first active region ACT1.

Referring to FIG. 2, the source/drain region SD of one side of each of the first source follower gate electrode SF1 and the second source follower gate electrode SF2 may be connected to a pixel voltage line MPL. The source/drain region SD of one side of each of the gate electrodes GE may be connected to the pixel voltage line MPL.

The source/drain region SD of the other side of each of the first source follower gate electrode SF1 and the second source follower gate electrode SF2 and the source/drain region SD of one side of the selection gate electrode SEL may be connected to an SF-SEL connection line SSL. The SF-SEL connection line SSL may have an “L” shape in a plan view. The source/drain region SD of the other side of the selection gate electrode SEL may be connected to an output line Vout. A connection relationship between other transistors may be the same as that of FIG. 4.

Referring to FIGS. 1 to 4, in the image sensor 100 according to the embodiment illustrated in FIGS. 1-4, the first to eighth pixels PX(1) to PX(8) arranged in the first and second pixel groups GRP1 and GRP2 may share the first and second source follower transistors S1 and S2, the reset transistor RX, the first and second dual conversion transistors DCX1 and DCX2, and the selection transistor SE.

In operation, electrons accumulated in the photoelectric conversion part PD may be moved to the floating diffusion region FD by turning on a transfer transistor (one of the first to eighth transfer transistors T1 to T8) in one of the pixels PX. Accordingly, a voltage level of the floating diffusion region FD may be changed. The reset transistor RX may reset the floating diffusion region FD. For example, in a state in which the first and second dual conversion transistors DCX1 and DCX2 are turned on, the reset transistor RX may electrically connect the floating diffusion region FD and a power voltage Vpix on the basis of an electrical signal (a reset signal) applied to the reset gate electrode RG. The reset transistor RX may remove or discharge electrons stored in the floating diffusion region FD by driving the floating diffusion region FD at a power voltage Vpix on the basis of a reset signal.

The first and second source follower transistors S1 and S2 may be connected in parallel and constitute a fingered-type source follower transistor SX. The source follower transistor SX may have the source follower gate electrode SF in which the first source follower gate electrode SF1 and the second source follower gate electrode SF2 are connected. The source follower gate electrode SF may be connected to the floating diffusion region FD.

The source follower transistor SX may be connected between the power voltage Vpix and the selection transistor SE. A voltage level of one end of the source follower transistor SX may be changed on the basis of a voltage level of the floating diffusion region FD, and when the selection transistor SE is turned on, an output signal may be transmitted through the output line Vout.

A source follower transistor may be more sensitive to effects of an intrinsic thermal noise and flicker noise of a transistor element than a transfer transistor, a reset transistor, and a selection transistor. A noise occurring in a source follower transistor element is transmitted to an internal circuit as it is, which leads to deterioration of image quality. Forming the source follower transistor as a fingered type may assist in reducing such an effect of an intrinsic thermal noise and flicker noise of a transistor element and fully reading potential of the floating diffusion region FD. In addition, the amount of current of the source follower transistor SX may be increased. Accordingly, linearity of a voltage-current graph of the source follower transistor SX may be improved, and noises such as a random noise and a random telegraphy signal may be reduced.

The first and second dual conversion transistors DCX1 and DCX2 may be connected between the floating diffusion region FD and the reset transistor RX. When the first and second dual conversion transistors DCX1 and DCX2 are turned off, full well capacity (FWC) of the pixel PX may be capacitance of the floating diffusion region FD. When at least one of the first or second dual conversion transistor DCX1 or DCX2 is turned on, FWC of the pixel PX may increase compared to capacitance of the floating diffusion region FD. The first and second dual conversion transistors DCX1 and DCX2 may be both turned off at low illuminance. The first dual conversion transistor DCX1 may be turned on, and the second dual conversion transistor DCX2 may be turned off at intermediate illuminance. The first and second dual conversion transistors DCX1 and DCX2 may be both turned on at high illuminance. A conversion gain of the pixel PX may be changed by turning on/off the first and second dual conversion transistors DCX1 and DCX2 according to illuminance as described above. Accordingly, a clear image having improved high dynamic range (HDR) characteristics may be provided.

In a case of a full mode, in the image sensor 100, a turn-on voltage may be sequentially applied to the first to eighth transfer gate electrodes TG(1) to TG(8) and a signal of each of the pixels PX may be output. In some embodiments, in a case of a binning mode, the turn-on voltage may be simultaneously applied to the transfer gate electrodes TG for each pixel group and a signal may be output for each pixel group.

A first buried line BFD may be provided in an upper portion of the substrate 1. The first buried line BFD may be provided on an upper surface of the isolation structure 10. The first buried line BFD may extend along the isolation structure 10. The first buried line BFD may have a mesh shape in a plan view. An upper surface of the first buried line BFD may be substantially coplanar with an upper surface of the first and second common floating diffusion regions FDC1 and FDC2. The first buried line BFD and the first and second common floating diffusion regions FDC1 and FDC2 may constitute a connection line FDL.

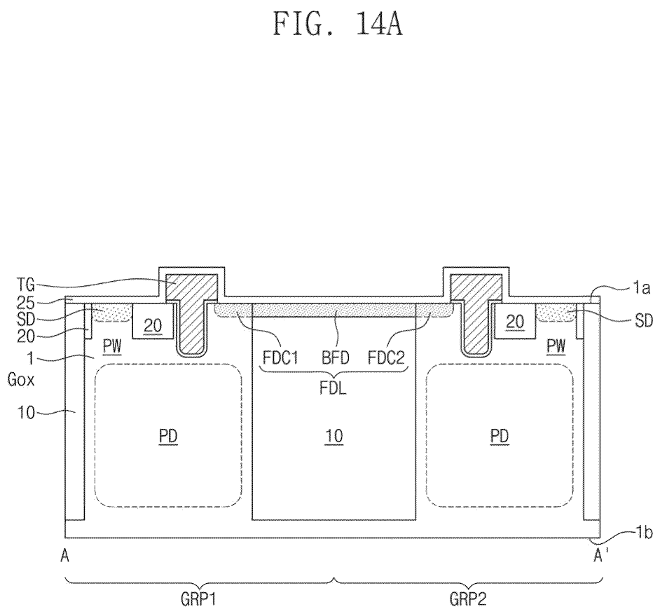

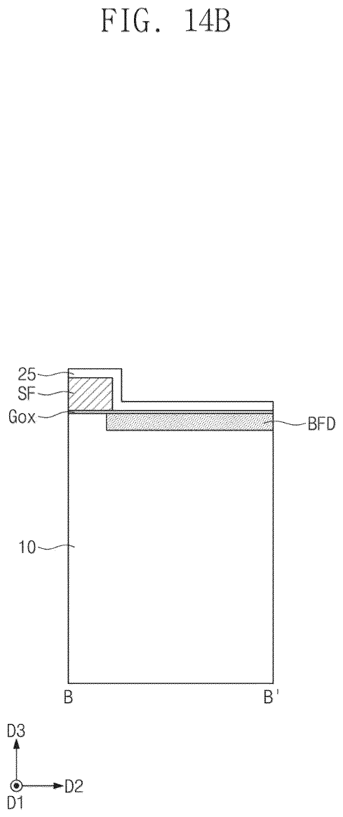

The upper surface of the first buried line BFD may be located at a lower level than an upper surface of the source follower gate electrode SF and an upper surface of the transfer gate electrode TG (best seen in FIG. 3). A bottom surface of the first buried line BFD may be located at a higher level than a bottom surface of the transfer gate electrode TG (best seen in FIG. 5; see also FIG. 14a described below). The transfer gate connection line TGL and the pixel voltage line MPL may be located at a higher level than the first buried line BFD.

The first buried line BFD may be in direct contact with each of the first common floating diffusion region FDC1, the second common floating diffusion region FDC2, and the source follower gate electrode SF. The first buried line BFD may electrically connect the first common floating diffusion region FDC1, the second common floating diffusion region FDC2, and the source follower gate electrode SF to each other. A boundary between the first buried line BFD and the first common floating diffusion region FDC1 and a boundary between the first buried line BFD and the second common floating diffusion region FDC2 may be unable to be visibly distinguished.

The first buried line BFD may include a first buried portion B1 extending from the first common floating diffusion region FDC1 in the first direction D1. The first buried line BFD may include a second buried portion B2 extending from the source follower gate electrode SF to the first buried portion B1 in the second direction D2. The first buried portion B1 and the second buried portion B2 may extend respectively in directions intersecting each other and may meet an contact each other. The first and second buried portions B1 and B2 may extend along the isolation structure 10. A width of the first buried portion B1 in the second direction and a width of the second buried portion B2 in the first direction D1 may be smaller than widths of the first and second common floating diffusion regions FDC1 and FDC2 in the second direction D2.

The first buried portion B1 may extend in the first direction D1 and electrically connect the first common floating diffusion region FDC1 and the second common floating diffusion region FDC2 to each other. At least a portion of the second buried portion B2 may vertically overlap the source follower gate electrode SF. In some embodiments, the first buried line BFD may extend and may be connected to the source/drain region SD of one side of the first dual conversion gate electrode DCG1.

The first buried line BFD may include a same material as a material of the first and second common floating diffusion regions FDC1 and FDC2. The first buried line BFD may include a semiconductor material. For example, in some embodiments, the first buried line BFD may include silicon.

Referring to FIGS. 5 and 6, a gate insulating film Gox may be interposed between the transfer gate electrode TG and the substrate 1. The gate insulating film Gox may be interposed between the gate electrodes RG, DCG1, DCG2, SF1, SF2, SEL, and GE of other driving transistors and the substrate 1. The gate insulating film Gox may include a single-layer or multi-layer of at least one of silicon oxide, metal oxide, silicon nitride, or silicon oxynitride. The transfer gate electrode TG and the gate electrodes RG, DCG1, DCG2, SF1, SF2, SEL, and GE may be formed of at least one of impurity-doped polysilicon or metal such as tungsten or aluminum. The transfer gate electrode TG and the gate electrodes RG, DCG1, DCG2, SF1, SF2, SEL, and GE may be formed of impurity-doped polysilicon.

The photoelectric conversion part PD disposed in the substrate 1 in a pixel PX may overlap a corresponding one of the transfer gate electrode TG and a corresponding one of the gate electrodes RG, DCG1, DCG2, SF1, SF2, SEL and GE (see FIGS. 1, 2, and 5). A side surface of the transfer gate electrode TG may be covered with a spacer 25. The spacer 25 may include a single-layer or multi-layer of at least one of silicon oxide, silicon nitride, or silicon oxynitride.

The first face la of the substrate 1 and the gate electrodes TG, RG, DCG1, DCG2, SF1, SF2, SEL, and GE may be covered with a first interlayer insulating layer IL1. The first interlayer insulating layer IL1 may include an etch stop film 3 and a planarization film 5. The etch stop film 3 may be conformally formed. The planarization film 5 may fill a space between the gate electrodes TG, RG, DCG1, DCG2, SF1, SF2, SEL, and GE. A lower surface of the planarization film 5 may be coplanar with an upper surface of the etch stop film 3 on the gate electrodes TG, RG, DCG1, DCG2, SF1, SF2, SEL, and GE. The etch stop film 3 may have etching selectivity with respect to the planarization film 5. The etch stop film 3 may be formed of, for example, SiN, SiCN, or SiON. The planarization film 5 may be formed of, for example, silicon oxide or a porous insulator.

First contact plugs 15a, 15b, and 15c may penetrate the first interlayer insulating layer IL1. The first contact plugs 15a, 15b, and 15c may include first gate contact plugs 15a, second gate contact plugs 15b, and a first source follower contact 15c. The first gate contact plugs 15a may penetrate the etch stop film 3 and the planarization film 5 of the first interlayer insulating layer IL1 to be in contact with corresponding ones of the gate electrodes TG, RG, DCG1, DCG2, SF1, SF2, and SEL. The second gate contact plugs 15b may penetrate the etch stop film 3 and the planarization film 5 of the first interlayer insulating layer IL1 to be in contact with corresponding ones of the source/drain regions SD. The first and second gate contact plugs 15a and 15b may include a conductive material. For example, in some embodiments, the first and second gate contact plugs 15a and 15b may include tungsten. In some embodiments, the first and second gate contact plugs 15a and 15b may be formed of impurity-doped polysilicon.

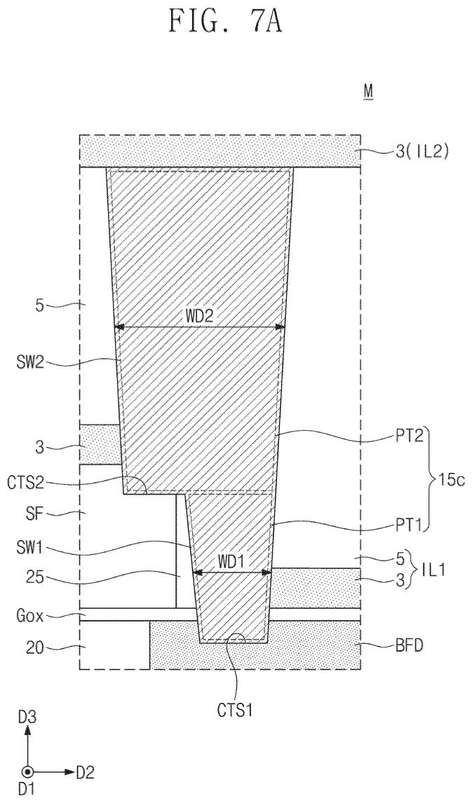

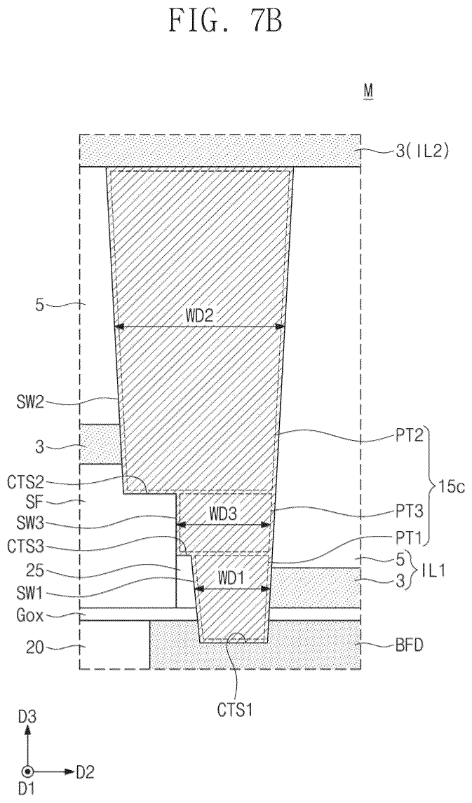

FIG. 7A is an enlarged view of region M of FIG. 6, according to some embodiments. The first source follower contact 15c will be described in more detail with reference to FIGS. 6 and 7A.

Referring to FIGS. 6 and 7A, the gate insulating film Gox may be provided on the device isolation structure 20 and the first buried line BFD. The gate insulating film Gox may include a single-layer or multi-layer of at least one of silicon oxide, metal oxide, silicon nitride, or silicon oxynitride. The source follower gate electrode SF and the spacer 25 may be provided on the gate insulating film Gox. The spacer 25 may cover a portion of a side surface of the source follower gate electrode SF. The first interlayer insulating layer IL1 may be provided on the source follower gate electrode SF and the gate insulating film Gox. Specifically, the etch stop film 3 and the planarization film 5 may be sequentially provided on an upper surface of each of the source follower gate electrode SF and the gate insulating film Gox.

The first source follower contact 15c may penetrate the etch stop film 3 and the planarization film 5 of the first interlayer insulating layer IL1 to be in contact with the source follower gate electrode SF and the first buried line BFD. A bottom surface CTS1 of the first source follower contact 15c may be in contact with the second buried portion B2 of the first buried line BFD. In other words, a lowermost surface of the first source follower contact 15c may be in contact with the second buried portion B2 of the first buried line BFD. A level of the bottom surface CTS1 of the first source follower contact 15c may be lower than a level of the upper surface of the first buried line BFD. A width of the first source follower contact 15c in the second direction D2 may be greater than widths of the first and second gate contact plugs 15a and 15b. In other words, a minimum width of the first source follower contact 15c in the second direction D2 may be greater than maximum widths of the first and second gate contact plugs 15a and 15b.

The first source follower contact 15c may include a first portion PT1 and a second portion PT2 on the first portion PT1. The first portion PT1 may be a portion being in direct contact with the first buried line BFD. A lower portion of the first portion PT1 may be buried in the first buried line BFD. The second portion PT2 may include a portion in direct contact with the source follower gate electrode SF.

The first portion PT1 may have a first sidewall SW1 adjacent to the source follower gate electrode SF. The second portion PT2 may have a second sidewall SW2 adjacent to the source follower gate electrode. The first sidewall SW1 may be offset from the second sidewall SW2 in the second direction D2. The first sidewall SW1 may be spaced apart from the second sidewall SW2 in the second direction D2. At least a portion of the first sidewall SW1 may be in contact with the spacer 25. The first sidewall SW1 may be spaced apart from the source follower gate electrode SF in the second direction D2. At least a portion of the second sidewall SW2 may be in direct contact with the source follower gate electrode SF and the etch stop film 3 of the first interlayer insulating layer IL1.

The second portion PT2 may include a first connection outer wall CTS2 extending in the second direction D2. The first connection outer wall CTS2 may connect the first sidewall SW1 and the second sidewall SW2. The first connection outer wall CTS2 may be in contact with the source follower gate electrode SF and the spacer 25. A level of the first connection outer wall CTS2 may be lower than a level of the upper surface of the source follower gate electrode SF. The level of the first connection outer wall CTS2 may be higher than the level of the upper surface of the first buried line BFD. The first connection outer wall CTS2 may be located on a boundary between the first portion PT1 and the second portion PT2.

Respective widths WD1 and WD2 of the first portion PT1 and the second portion PT2 may increase in a vertical direction D3 away from the bottom surface CTS1 of the first source follower contact 15c. A maximum width of the first portion PT1 may be smaller than a minimum width of the second portion PT2. A difference between the maximum width of the first portion PT1 and the minimum width of the second portion PT2 may be equal to a width of the first connection outer wall CTS2. A width of the first source follower contact 15c may be discontinuously changed on a boundary between the first portion PT1 and the second portion PT2.

An upper surface of the first source follower contact 15c may be in contact with an etch stop film 3 of a second interlayer insulating layer IL2 to be described later. A first lining layer M1 may be omitted on the first source follower contact 15c. As a result, a degree of freedom for lining layers in second to fourth interlayer insulating layers IL2, IL3, and IL4 may be increased. In some embodiments, the first lining layer M1 may be provided on the first source follower contact 15c.

FIG. 7B is an enlarged view of region M of FIG. 6, according to some embodiments.

Referring to FIG. 7B, a third portion PT3 may be interposed between a first portion PT1 and a second portion PT2 of the first source follower contact 15c. The third portion PT3 may include a third sidewall SW3 being in contact with a source follower gate electrode SF. The third sidewall SW3 may be offset from a second sidewall SW2 in the second direction D2. The third sidewall SW3 may be spaced apart from the second sidewall SW2 in the second direction D2. A first sidewall SW1 may be spaced apart from the third sidewall SW3 in the second direction D2.

The third portion PT3 may include a second connection outer wall CTS3 extending in the second direction D2. At least a portion of the second connection outer wall CTS3 may be in contact with a spacer 25. The second connection outer wall CTS3 may connect the first sidewall SW1 and the third sidewall SW3. A level of the second connection outer wall CTS3 may be lower than a level of a first connection outer wall CTS2. The level of the second connection outer wall CTS3 may be located between the level of the first connection outer wall CTS2 and a level of a bottom surface CTS1 of a first source follower contact 15c.

A width WD3 of the third portion PT3 may increase in the vertical direction D3 away from the bottom surface CTS1 of the first source follower contact 15c. A minimum width of the third portion PT3 may be greater than a maximum width of the first portion PT1. A maximum width of the third portion PT3 may be smaller than a minimum width of the second portion PT2. A difference between the minimum width of the third portion PT3 and the maximum width of the first portion PT1 may be equal to a width of the second connection outer wall CTS3. A difference between the maximum width of the third portion PT3 and the minimum width of the second portion PT2 may be equal to a width of the first connection outer wall CTS2.

A width of the first source follower contact 15c may be discontinuously changed on a boundary between the first portion PT1 and the third portion PT3. A width of the first source follower contact 15c may be discontinuously changed on a boundary between the second portion PT2 and the third portion PT3. Accordingly, the first source follower contact 15c may include at least one discontinuous change in width.

The first and second common floating diffusion regions FDC1 and FDC2 may be electrically connected to the first source follower contact 15c through the first buried line BFD. Accordingly, a gate contact may be omitted on the first and second common floating diffusion regions FDC1 and FDC2.

Referring to FIGS. 1 to 6, an image sensor according to various embodiments may include the first buried line BFD connecting the source follower gate electrode SF and the first and second common floating diffusion regions FDC1 and FDC2 to each other. Since the first buried line BFD is buried in the substrate 1, a degree of freedom in designing a line arrangement may be increased.

In addition, a gate contact directly connected to the first and second common floating diffusion regions FDC1 and FDC2 may be omitted on the first and second common floating diffusion regions FDC1 and FDC2. Accordingly, junction leakage which occurs between the first and second common floating diffusion regions FDC1 and FDC2 and the gate contact may be prevented/reduced.

Returning to FIG. 5, the second to fourth interlayer insulating layers IL2, IL3, and IL4 may be sequentially stacked on the first interlayer insulating layer IL1. At least a portion of the second to fourth interlayer insulating layers IL2, IL3, and IL4 may include an etch stop film 3 and a planarization film 5 which are sequentially stacked. The transfer gate connection line TGL, the SF-SEL connection line SSL, and first lining layer M1 may be arranged in the second interlayer insulating layer IL2. A second contact plug 23 may penetrate the third interlayer insulating layer IL3 and may be connected to at least one of the first lining layer M1. Second lining layer M2 may be arranged on the third interlayer insulating layer IL3.

A fixed charge film 24 may be disposed on the second face 1b of the substrate 1 to be in contact with the second face 1b. The fixed charge film 24 may be in contact with the second face 1b. The fixed charge film 24 may include a metal oxide film or metal fluoride film including an insufficient amount of oxygen or fluorine compared to a stoichiometric ratio. Accordingly, the fixed charge film 24 may have a negative fixed charge. The fixed charge film 24 may be formed of a metal oxide or metal fluoride including at least one metal selected from the group including hafnium (Hf), zirconium (Zr), aluminum (Al), tantalum (Ta), titanium (Ti), yttrium, and lanthanoid. Hole accumulation may occur around the fixed charge film 24. Therefore, occurrence of dark current and a white spot may be effectively reduced. The fixed charge film 24 may be at least one of an aluminum oxide film or a hafnium oxide film.

An anti-reflective film 42 may be disposed under the fixed charge film 24. The anti-reflective film 42 may include, for example, silicon nitride. A first grid pattern 48a and a second grid pattern 50a may be sequentially stacked on the anti-reflective film 42. The first grid pattern 48a and the second grid pattern 50a may have a mesh shape in a plan view. The first grid pattern 48a and the second grid pattern 50a may expose the anti-reflective film 42.

A sidewall of the second grid pattern 50a may be aligned with a sidewall of the first grid pattern 48a. The first grid pattern 48a and the second grid pattern 50a may prevent crosstalk between adjacent pixels. The first grid pattern 48a may include a material that does not transmit light, for example, titanium or tungsten. The second grid pattern 50a may include an organic material. The second grid pattern 50a may have a lower refractive index than color filters CF1 and CF2. For example, the second grid pattern 50a may have a refractive index of about 1.3 or less.

A plurality of color filters may be arranged on the anti-reflective film 42. In some embodiments, the plurality of color filters may include a first color filter CF1 and a second color filter CF2. The color filters CF1 and CF2 may have a different color for each of the pixel groups GRP1 and GRP2. That is, the first color filter CF1 may be disposed under the first pixel group GRP1. The first to fourth pixels PX(1) to PX(4) of the first pixel group GRP1 may be covered with the first color filter CF1 of the same color. The second color filter CF2 may be disposed under the second pixel group GRP2. The fifth to eighth pixels PX(5) to PX(8) of the second pixel group GRP2 may be covered with the second color filter CF2 of the same color.

The first and second color filters CF1 and CF2 may include a photoresist material to which dye or a pigment is added. The plurality of color filters may be arranged two-dimensionally along the first direction D1 and the second direction D2 constituting a color filter array. The color filter array may have an RGB pattern formed of red (R), green (G), and blue (B), or an RGBW pattern including a white pixel. The white pixel may be a pixel that senses light of all colors or all of visible light. A color filter may be omitted on the white pixel, and a portion of a microlens ML may be located thereon instead of a color filter. The color filter array may have a complementary color pattern formed of cyan, yellow, and magenta. The color filter array may have a form of a Bayer pattern, a 2×2 tetra pattern, a 3×3 nona pattern, and a 4×4 hexadeca pattern.

Microlenses ML may be arranged under the first and second color filters CF1 and CF2. End portions of the microlenses ML may be in contact with and connected to each other. The first pixel group GRP1 may be covered with one microlens ML. The second pixel group GRP2 may be covered with another microlens ML. The image sensor 100 may perform an autofocusing function by shifting a phase of an output value of the pixels PX in different positions in one pixel group GRP1 or GRP2.

The image sensor 100 may be also operated in a global shutter mode. To be operated in the global shutter mode, the image sensor 100 may further include a pre-charge transistor, a sampling transistor, a capacitor, and/or the like connected to the output line Vout.

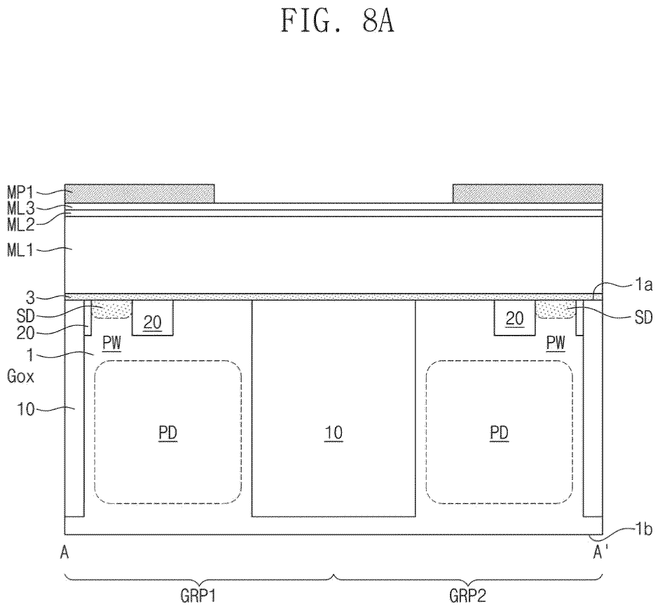

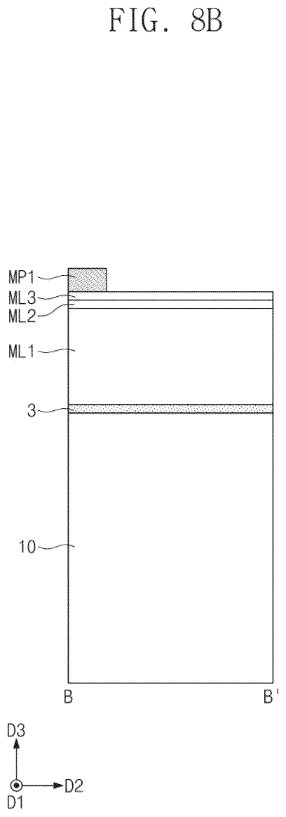

FIGS. 8A to 16B are diagrams for describing a method for manufacturing an image sensor according to some embodiments. Specifically, FIGS. 8A, 9A, 10A, 11A, 12A, 13A, 14A, 15A, and 16A are cross-sectional views taken along line A-A′ of FIG. 2. FIGS. 8B, 9B, 10B, 11B, 12B, 13B, 14B, 15B, and 16B are cross-sectional views taken along line B-B′ of FIG. 2.

Referring to FIGS. 1, 8A, and 8B, a substrate 1 including a first face la and a second face 1b opposing each other may be provided. A well region PW, a isolation structure 10, a device isolation structure 20, and a photoelectric conversion part PD may be formed in the substrate 1. A lower surface of the isolation structure 10 may be spaced apart from the second face 1b of the substrate 1. Source/drain regions SD may be formed in the substrate 1.

An etch stop film 3, a first mold film ML1, a second mold film ML2, and a third mold film ML3 may be sequentially formed on the first face la of the substrate 1. The first mold film ML1 may include a material having etching selectivity with respect to a material of the etch stop film 3 and the isolation structure 10. For example, the first mold film ML1 may be a spin on hardmask (SOH). The second and third mold films ML2 and ML3 may include a material having etching selectivity with respect to the material of the first mold film ML1.

A first mask pattern MP1 may be formed on the third mold film ML3. The first mask pattern MP1 may include a material having etching selectivity with respect to the first mold film ML1.

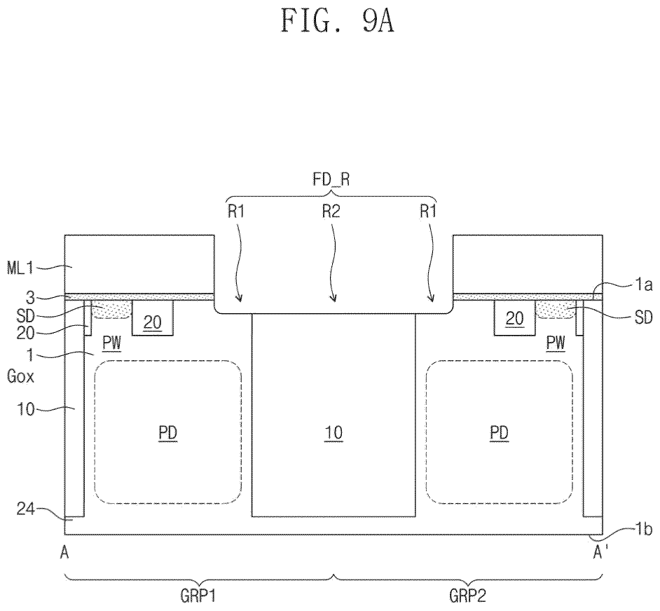

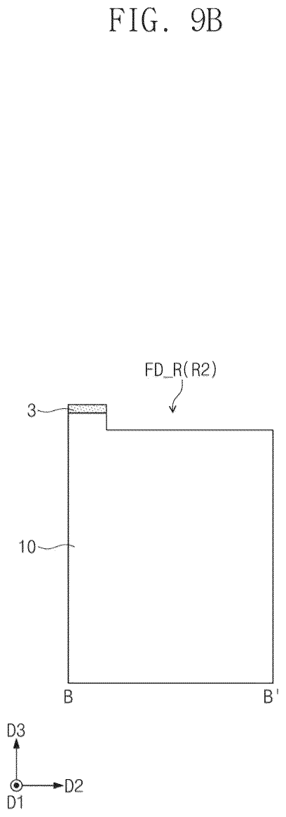

Referring to FIGS. 9A and 9B, the first to third mold films ML1, ML2, and ML3 may be etched by performing an etching process using the first mask pattern MP1 as a mask. Thereafter, the second and third mold films ML2 and ML3 may be removed. A height of the first mold film ML1 may be reduced.

An etching process may be performed using the first mold film ML1 as a mask. A first etched portion FD_R may be formed by etching the etch stop film 3, an upper portion of the isolation structure 10, and an upper portion of the substrate 1 through the etching process. The first etched portion FD_R may include a first recess R1 exposing the etched substrate 1 and a second recess R2 exposing the etched isolation structure 10. A bottom surface of the first recess R1 and a bottom surface of the second recess R2 may be located at the same level. For example, in some embodiments, the bottom surface of the first recess R1 and the bottom surface of the second recess R2 may be coplanar. In some embodiments, the bottom surface of the first recess R1 and the bottom surface of the second recess R2 may be located at different levels.

The second recess R2 may include a first recess portion and a second recess portion. The first recess portion may correspond to the first buried portion B1 of FIG. 1, and the second recess portion may correspond to the second buried portion B2 of FIG. 1. The first recess portion may extend from the first recess R1 in a first direction D1. The second recess portion may extend from the first recess portion in a second direction D2.

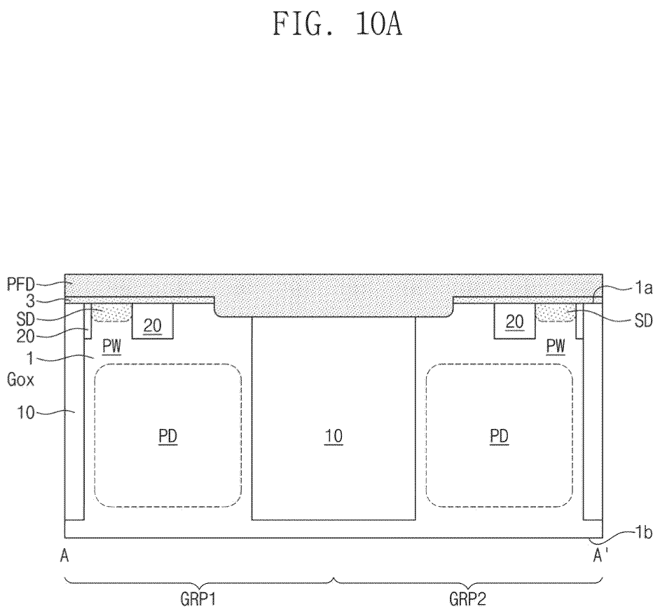

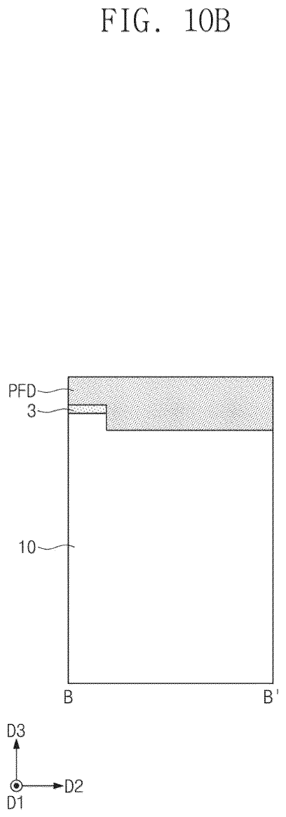

Referring to FIGS. 10A and 10B, a diffusion film PFD may be formed on the etch stop film 3 and the first etched portion FD_R. The diffusion film PFD may include a semiconductor material. For example, in some embodiments, the diffusion film PFD may include poly silicon.

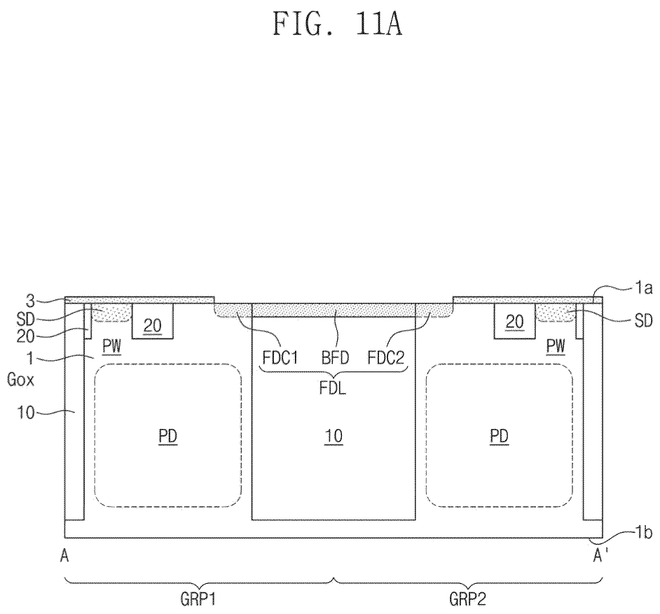

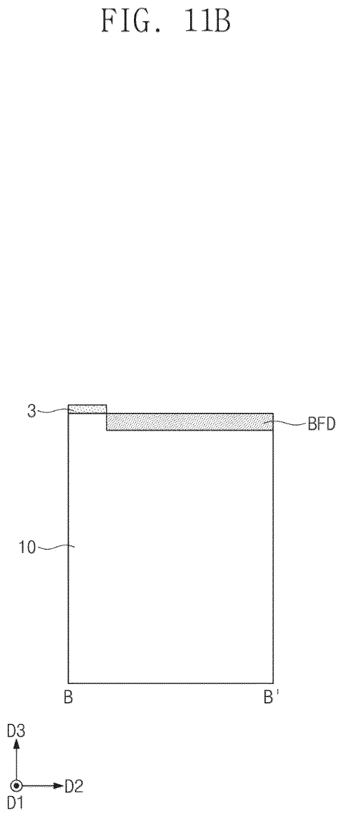

Referring to FIGS. 11A and 11B, the diffusion film PFD may be etched, and a connection line FDL may be formed by performing an etch back and/or chemical mechanical polishing (CMP) process on the diffusion film PFD. Specifically, forming the connection line FDL may include forming first and second common floating diffusion regions FDC1 and FDC2 in the first recess R1 and forming a first buried line BFD in the second recess R2.

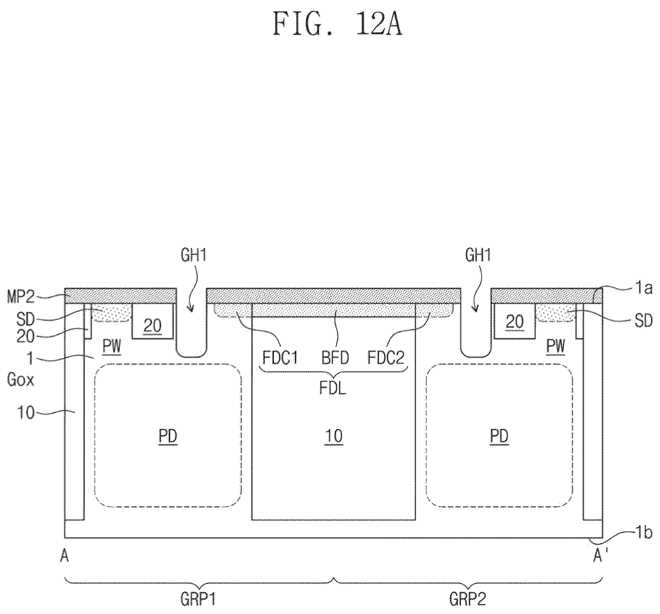

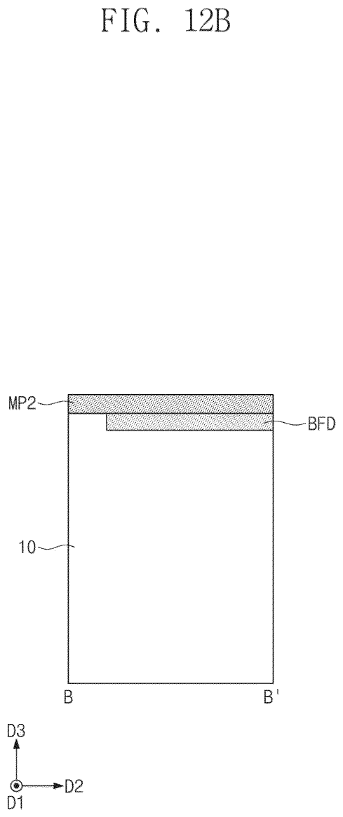

Referring to FIGS. 12A and 12B, the etch stop film 3 on the substrate 1 may be removed, and second mask patterns MP2 may be formed. The second mask patterns MP2 may include a material having etching selectivity with respect to the substrate 1. For example, the second mask patterns MP2 may include SiON.

Gate holes GH1 may be formed by etching an upper portion of the substrate 1 using the second mask patterns MP2 as a mask. A level of a bottom surface of the gate holes GH1 may be lower than a level of a bottom surface of the first buried line BFD.

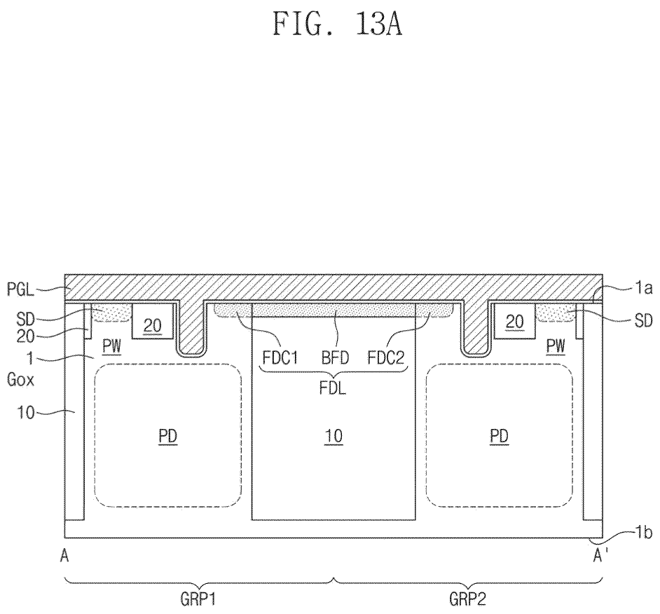

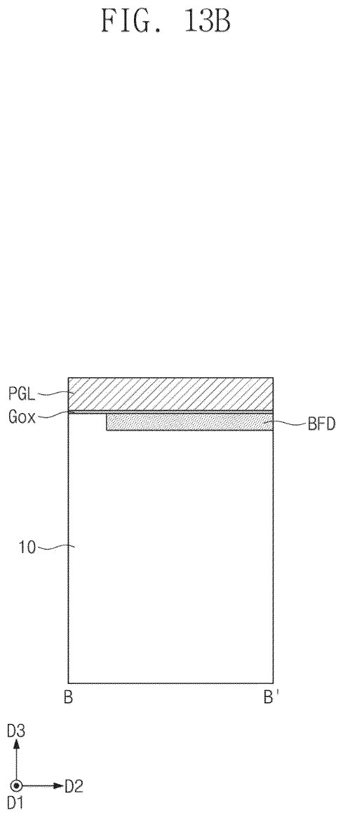

Referring to FIGS. 13A and 13B, a gate insulating film Gox may be conformally formed on the first face la of the substrate 1 and the gate holes GH1. The gate insulating film Gox may include a single-layer or multi-layer of at least one of silicon oxide, metal oxide, silicon nitride, or silicon oxynitride.

A preliminary gate film PGL may be formed on the gate insulating film Gox. The preliminary gate film PGL may include a metal material. For example, in some embodiments, the preliminary gate film PGL may include at least one of impurity-doped polysilicon, tungsten, or aluminum.

Referring to FIGS. 14A and 14B, a transfer gate electrode TG and gate electrodes RG, DCG1, DCG2, SF, SEL, and GE of driving transistors may be formed by etching the gate insulating film Gox and the preliminary gate film PGL through a patterning process.

A spacer film 25 may be conformally formed on a front side of the substrate 1. For example, the spacer film 25 may cover an upper surface and sidewalls of the transfer gate electrode TG and the source follower gate electrode SF as illustrated in FIGS. 14A and 14B. The spacer film 25 may include a single-layer or multi-layer of at least one of silicon oxide, silicon nitride, or silicon oxynitride.

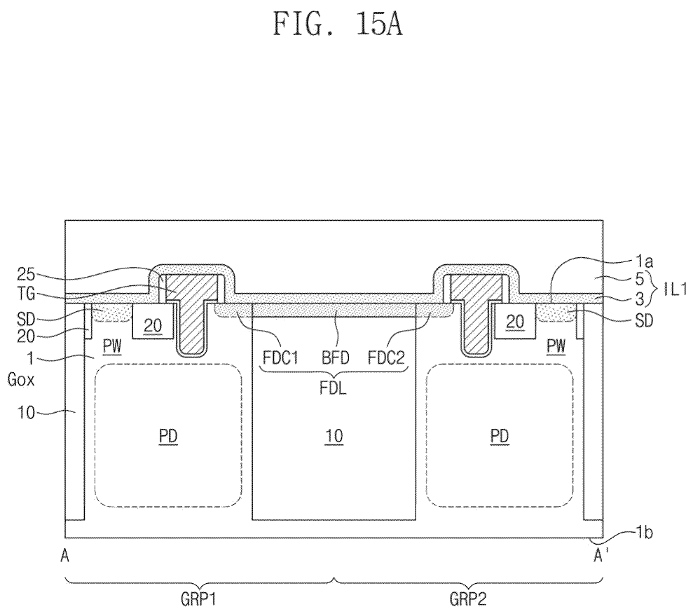

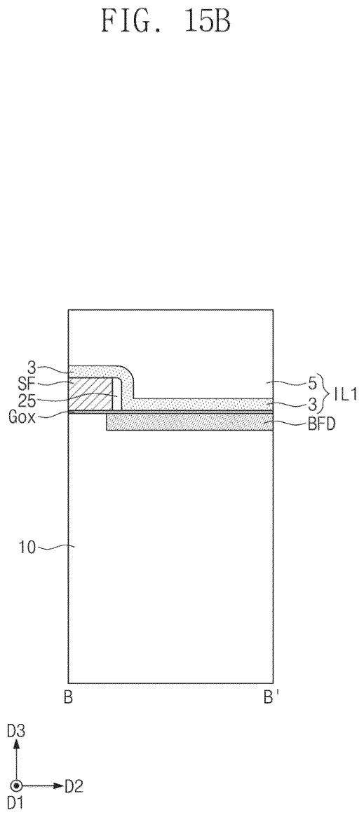

Referring to FIGS. 15A and 15B, a spacer 25 may be formed by etching the spacer film 25 through a patterning process. The spacer 25 may be formed on sidewalls of the transfer gate electrode TG and on sidewalls of each of gate electrodes RG, DCG1, DCG2, SF, SEL, and GE of driving transistors.

An etch stop film 3 is conformally stacked on the first face la of the substrate 1. A planarization film 5 is stacked on the etch stop film 3, and in some embodiments, the planarization film 5 may have a flat upper surface by performing a chemical mechanical polishing (CMP) process. The planarization film 5 may be formed to fill a space between the transfer gate electrode TG and gate electrodes RG, DCG1, DCG2, SF1, SF2, SEL, DM1, and DM2 and may have a flat upper surface. Accordingly, a first interlayer insulating layer IL1 including the etch stop film 3 and the planarization film 5 may be formed.

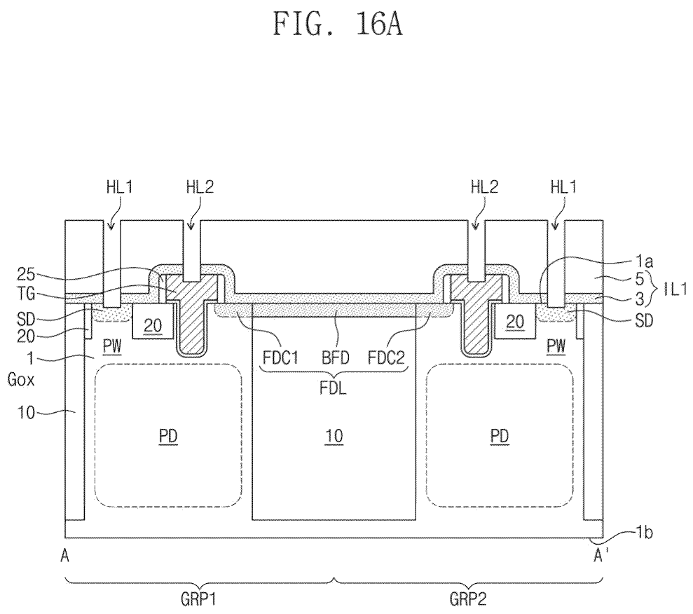

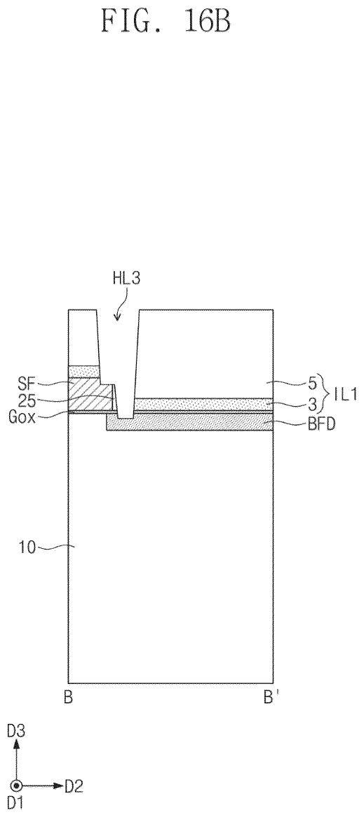

Referring to FIGS. 16A and 16B, first contact holes HL1, second contact holes HL2, and a third contact hole HL3 may be formed by etching the first interlayer insulating layer IL1 through a patterning process. The first contact holes HL1 may penetrate the planarization film 5 and the etch stop film 3 of the first interlayer insulating layer IL1 and expose the source/drain regions SD. The second contact holes HL2 may penetrate the planarization film 5 and the etch stop film 3 of the first interlayer insulating layer IL1 and expose the corresponding transfer gate electrode TG and the corresponding gate electrodes RG, DCG1, DCG2, SEL, and GE of the driving transistors.

The third contact hole HL3 may penetrate the planarization film 5 and the etch stop film 3 of the first interlayer insulating layer IL1 and expose the source follower gate electrode SF and the first buried line BFD. A width of the third contact hole HL3 may decrease toward a bottom surface of the first buried line BFD. The width of the third contact hole HL3 may be discontinuously changed. This structural configuration is because the source follower gate electrode SF, the spacer 25, and the first buried line BFD have etching selectivity different from each other with respect to an etching process of the patterning process.

Referring back to FIG. 5, first contact plugs 15a and 15b and a first source follower contact 15c may be formed by filling the first to third contact holes HL1, HL2, and HL3 with a conductive material.

A second interlayer insulating layer IL2 may be formed on the first interlayer insulating layer IL1. A transfer gate connection line TGL, an SF-SEL connection line SSL, and first lining layer M1 may be formed in the second interlayer insulating layer IL2 by performing an etching process, a plating process, a CMP process, and the like.

A third interlayer insulating layer IL3, second contact plugs 23, a fourth interlayer insulating layer IL4, second lining layer M2, and the like are formed on the second interlayer insulating layer IL2.

A portion of the substrate 1 may be removed by performing a back grinding process on the second face 1b of the substrate 1, and the isolation structure 10 may be exposed.

Thereafter, referring to FIG. 5, a fixed charge film 24, an anti-reflective film 42, a first grid pattern 48a and a second grid pattern 50a, color filters CF1 and CF2, microlenses ML, etc., are formed on the second face 1b of the substrate 1.

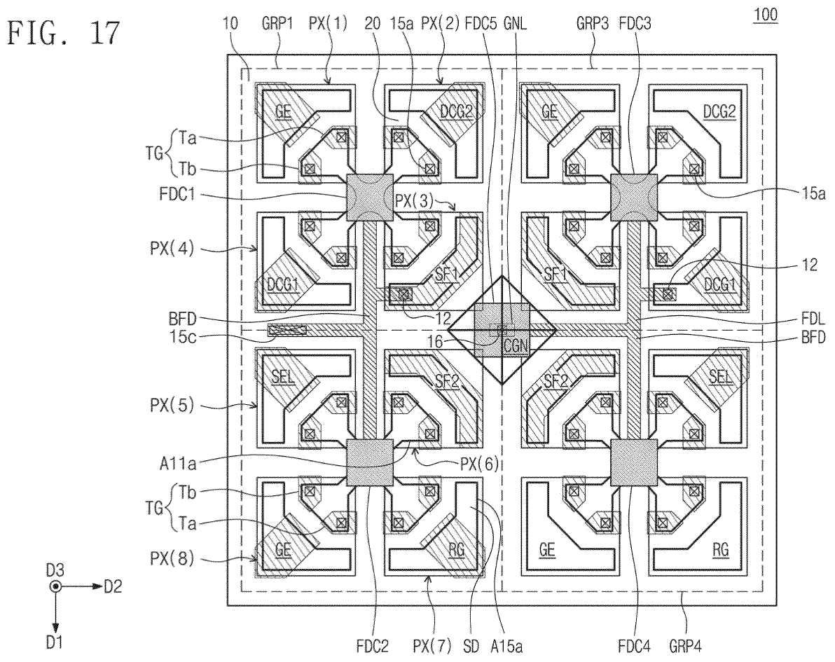

FIG. 17 is a plan view of an image sensor according to some embodiments.

Referring to FIG. 17, a third pixel group GRP3 adjacent to a first pixel group GRP1 in the second direction D2 and a fourth pixel group GRP4 adjacent to a second pixel group GRP2 in the second direction D2 may be disposed on the substrate 1. The fourth pixel group GRP4 may be disposed under the third pixel group GRP3.

A third common floating diffusion region FDC3 may be provided at a center of the third pixel group GRP3. A fourth common floating diffusion region FDC4 may be provided at a center of the fourth pixel group GRP4. The third and fourth common floating diffusion regions FDC3 and FDC4 may be substantially the same as first and second common floating diffusion regions FDC1 and FDC2.

The first to fourth pixel groups GRP1 to GRP4 may form a first sharing group. A first buried pattern FDC5 may be provided at a center of the first sharing group. The first buried pattern FDC5 may be an extending and expanding portion of a first buried line BFD. In some embodiments, the first buried pattern FDC5 may include poly silicon.

A common ground region CGN may be provided on the first buried pattern FDC5. In some embodiments, the ground region CGN may be doped with a first-conductive type impurity. The ground region CGN may be doped with an impurity of a different conductive type from a conductive type of the first and second common floating diffusion regions FDC1 and FDC2. A concentration of an impurity of the common ground region CGN may be higher than a concentration of an impurity of the well region PW of the substrate 1. The common ground region CGN may be formed by connecting respective ground regions CGN of the first to fourth pixel groups GRP1 to GRP4 to each other.

The common ground region CGN may be connected to a ground line GNL through a ground contact 16. The ground contact 16 may penetrate the first interlayer insulating layer IL1 and may be connected to the common ground region CGN. The ground line GNL may be provided in the second interlayer insulating layer IL2.

According to some embodiments, since the common ground region CGN is formed on the first buried pattern FDC5, the common ground region CGN may be omitted in a pixel region of the first to fourth pixel groups GRP1 to GRP4. Accordingly, a gate electrode of an existing dummy transistor may be used as a gate electrode of a driving transistor.

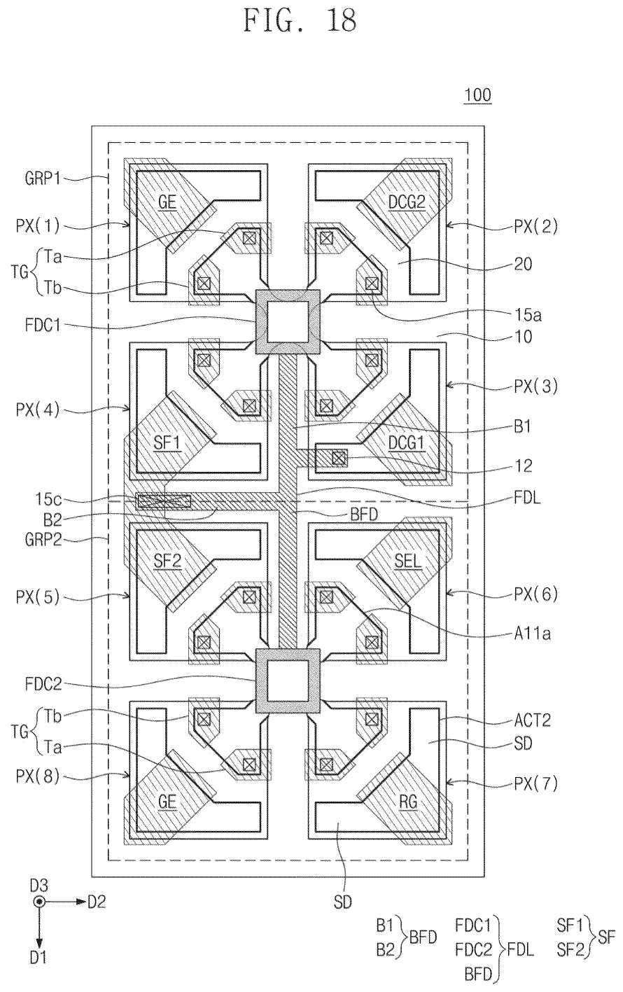

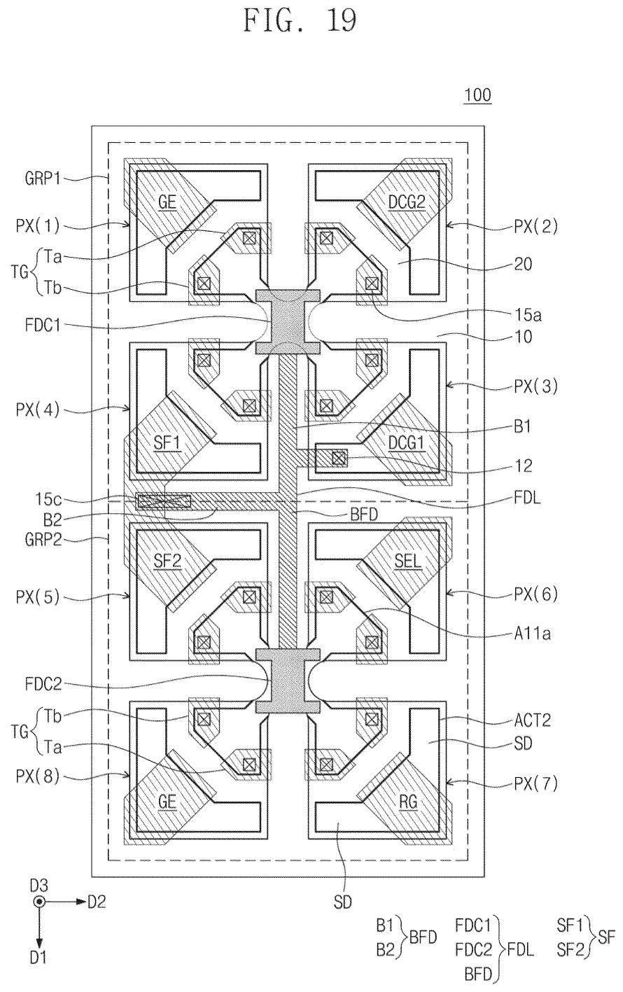

FIGS. 18 and 19 are plan views of an image sensor according to various embodiments. FIGS. 18 and 19 are plan views of an image sensor corresponding to FIG. 1.

Referring to FIGS. 18 and 19, a profile in a plan view of first and second common floating diffusion regions FDC1 and FDC2 may be various. In some embodiments, the first and second common floating diffusion regions FDC1 and FDC2 may have a profile of a quadrangle without a center portion, as illustrated in FIG. 18. The first and second common floating diffusion regions FDC1 and FDC2 may vertically overlap first active regions ACT1 of first to fourth pixels PX(1) to PX(4). In some embodiments, the first and second common floating diffusion regions FDC1 and FDC2 may have a doughnut profile. In some embodiments, the first and second common floating diffusion regions FDC1 and FDC2 may have a profile in which each of sidewalls opposing each other is recessed toward a center, as illustrated in FIG. 19. In various embodiments, the first and second common floating diffusion regions FDC1 and FDC2 may have various polygonal profiles.

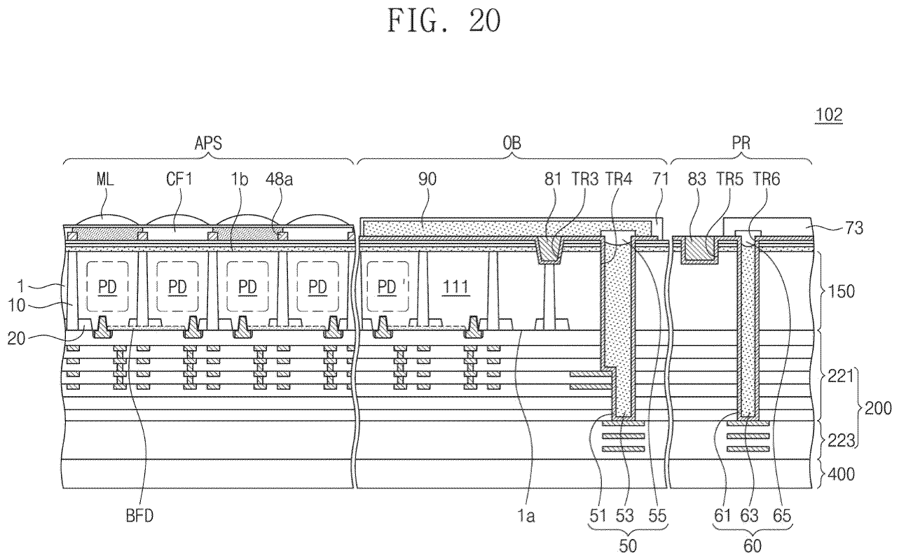

FIG. 20 is a cross-sectional view of an image sensor according to some embodiments.

Referring to FIG. 20, an image sensor 102 may include a substrate 1 having a pixel array region APS, an optical black region OB, and a pad region PR, a lining layer 200 on a first face la of the substrate 1, and a base substrate 400 on the lining layer 200.

The lining layer 200 may include an upper lining layer 221 and a lower lining layer 223. The pixel array region APS may include the pixels PX described with reference to FIGS. 1 to 6.

A first connection structure 50, a first conductive pad 81, and a bulk color filter 90 may be provided on the substrate 1 in the optical black region OB. The first connection structure 50 may include a first light shielding pattern 51, an insulating pattern 53, and a first capping pattern 55. The first light shielding pattern 51 may be formed of a conductive material. The first light shielding pattern 51 may include, for example, titanium or tungsten.

The first light shielding pattern 51 may be provided on a second face 1b of the substrate 1. The first light shielding pattern 51 may conformally cover an inner wall of a fourth trench TR4 and a third trench TR3. The first light shielding pattern 51 may penetrate a photoelectric conversion layer 150 and the upper lining layer 221 and connect the photoelectric conversion layer 150 and the lining layer 200.

The first light shielding pattern 51 may be in contact with an isolation conductive pattern of the isolation structure 10 of FIG. 2. The first conductive pad 81 may be electrically connected to the isolation conductive pattern of the isolation structure 10. The first light shielding pattern 51 may block light incident into the optical black region OB.

The first conductive pad 81 may be provided inside the third trench TR3 and fill a remaining portion of the third trench TR3. The first conductive pad 81 may include a metal material, for example, aluminum. A negative bias voltage may be applied to the isolation conductive pattern 14 through the first conductive pad 81. Accordingly, a white spot or dark current may be prevented/reduced.

The insulating pattern 53 may fill a remaining portion of the fourth trench TR4. The insulating pattern 53 may penetrate all of or a portion of the photoelectric conversion layer 150 and the lining layer 200. The first capping pattern 55 may be provided on an upper surface of the insulating pattern 53. The first capping pattern 55 may be provided on the insulating pattern 53.

The bulk color filter 90 may be provided on the first conductive pad 81, the first light shielding pattern 51, and the first capping pattern 55. The bulk color filter 90 may cover the first conductive pad 81, the first light shielding pattern 51, and the first capping pattern 55. A first protective film 71 may be provided on the bulk color filter 90 and encapsulate the bulk color filter 90.

A plurality of pixels PX may be also disposed in the optical black region OB, and a first reference photoelectric conversion part PD′ and a second reference region 111 may be disposed in the pixels PX. The first reference photoelectric conversion part PD′ provides a first reference charge amount that may be generated in a state in which light is blocked. The first reference charge amount may be a relative reference value when calculating the amount of charge generated from the pixels PX. The second reference region 111 provides a second reference charge amount that may be generated in a state in which the photoelectric conversion part PD is not provided. The second reference charge amount may be used as information for removing process noise.

A second connection structure 60, a second conductive pad 83, and a second protective film 73 may be provided on the substrate 1 in the pad region PR. The second connection structure 60 may include a second light shielding pattern 61, an insulating pattern 63, and a second capping pattern 65.

The second light shielding pattern 61 may be provided on the second face 1b of the substrate 1. The second light shielding pattern 61 may conformally cover an inner wall of a sixth trench TR6 and a fifth trench TR5. The second light shielding pattern 61 may penetrate the photoelectric conversion layer 150 and the upper lining layer 221 and connect the photoelectric conversion layer 150 and the lining layer 200. The second light shielding pattern 61 may be in contact with lines in the lower lining layer 223. The second light shielding pattern 61 may be electrically connected to lines in the lining layer 200. The second light shielding pattern 61 may include a metal material, for example, titanium or tungsten.

The second conductive pad 83 may be provided inside the fifth trench TR5 and fill a remaining portion of the fifth trench TR5. The second conductive pad 83 may include a metal material, for example, aluminum. The second conductive pad 83 may serve as an electrical connection path to the outside of an image sensor device. The insulating pattern 63 may fill a remaining portion of the sixth trench TR6. The insulating pattern 63 may penetrate all of or a portion of the photoelectric conversion layer 150 and the lining layer 200. The second capping pattern 65 may be provided on the insulating pattern 63. The second protective film 73 may cover a portion of the second light shielding pattern 61 and the second capping pattern 65.

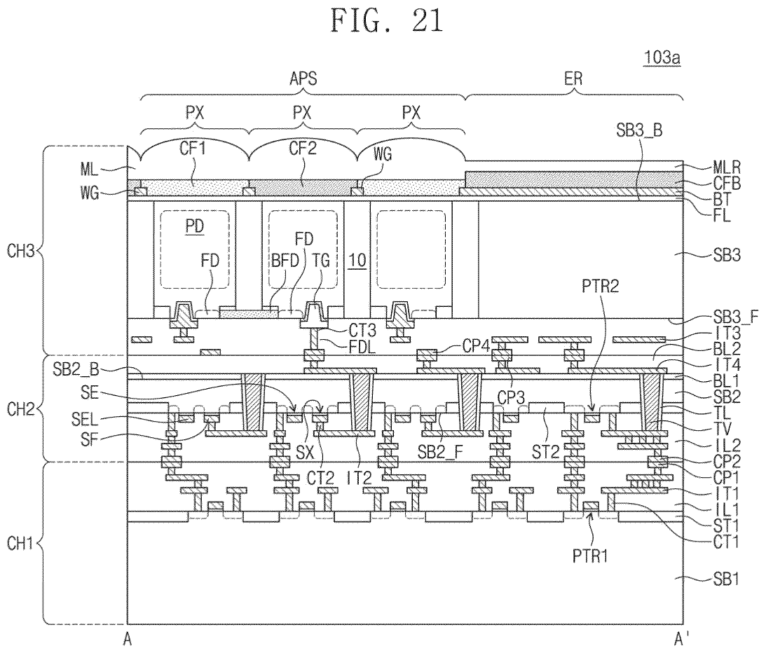

A structure of an image sensor described with reference to FIGS. 1 to 6 may be also applied to an image sensor with a 3-chip structure like that of FIG. 21 below.

FIG. 21 is a cross-sectional view of an image sensor according to some embodiments.

Referring to FIG. 21, an image sensor 103a may have a structure in which a first sub-chip CH1, a second sub-chip CH2, and a third sub-chip CH3 are sequentially stacked. The first sub-chip CH1 includes a first substrate SB1 and a first interlayer insulating layer IL1 covering a front side of the first substrate SB1. The first substrate SB1 may be a semiconductor substrate or insulating substrate. The first interlayer insulating layer IL1 may have a single-layer or multi-layer structure of at least one of SiO2, SiN, SiCN, SiON, or SiOCH. Logic circuits may be arranged in the first sub-chip CH1. The logic circuits may include a row driver, a row decoder, a column decoder, a timing generator, a correlated double sampler (CDS), an analog-to-digital converter (ADC), etc. First peripheral transistors PTR1, first contact plugs CT1, and first lines IT1 may be arranged on the first substrate SB1 so as to constitute the logic circuits. A first device isolation part ST1 may be disposed on the first substrate SB1 so as to define an active region for the first peripheral transistors PTR1. First conductive pads CP1 may be arranged at an upper end of the first interlayer insulating layer IL1.

The second sub-chip CH2 is bonded onto the first sub-chip CH1. The second sub-chip CH2 may include a second substrate SB2. A front side SB2_F of the second substrate SB2 may be covered with a second interlayer insulating layer IL2. The front side SB2_F of the second substrate SB2 may face the first sub-chip CH1. The driving transistors RX, DCX1, DCX2, SX, and SE illustrated in FIG. 4 may be arranged on the front side SB2_F of the second substrate SB2 in a main region of the second sub-chip CH2. Each of the gate electrodes RG, DCG1, DCG2, SF1, SF2, and SEL may have a shape of a planar type or vertical type. The driving transistors RX, DCX1, DCX2, S1, S2, and SE may have a fin field-effect transistor (FinFET), multi bridge channel FET (MBCFET), or gate all around FET (GAAFET) structure.

Second peripheral transistors PTR2 may be arranged on the front side SB2_F of the second substrate SB2 in a peripheral region of the second sub-chip CH2. A second device isolation part ST2 may be disposed on the front side SB2_F of the second substrate SB2 so as to define an active region for the driving transistors RX, DCX1, DCX2, SX, and SE and the second peripheral transistors PTR2. Second contact plugs CT2 and second lines IT2 may be arranged in the second interlayer insulating layer IL2. Second conductive pads CP2 may be arranged at a lower end of the second interlayer insulating layer IL2. A lower surface of the second interlayer insulating layer IL2 may be in contact with an upper surface of the first interlayer insulating layer IL1. The second conductive pads CP2 may be in contact with the first conductive pads CP1, respectively. There may be no boundary surface between the second conductive pads CP2 and the first conductive pads CP1 that are respectively in contact with the second conductive pads CP2, and the first and second conductive pads CP1 and CP2 corresponding to each other may be integrated.

A rear side SB2_B of the second substrate SB2 may be sequentially covered with first and second rear insulating films BL1 and BL2. Fourth lines IT4 may be arranged in the second rear insulating film BL2. Third conductive pads CP3 may be arranged at an upper end of the second rear insulating film BL2. Through vias TV may penetrate the first rear insulating film BL1, the second substrate SB2, the second device isolation part ST2, and a portion of the second interlayer insulating layer IL2. The through vias TV may be tapered downward. A via insulating film TL may be interposed between the through vias TV and the second substrate SB2.

The third sub-chip CH3 is bonded onto the second sub-chip CH2. The third sub-chip CH3 includes a third substrate SB3. The third substrate SB3 may include a pixel array region APS and an edge region ER. The pixel array region APS may include a plurality of pixels PX. A isolation structure 10 may be disposed in the third substrate SB3 and may isolate the pixels PX from each other. A photoelectric conversion part PD is disposed in the third substrate SB3 in each of the pixels PX. A front side SB3_F of the third substrate SB3 may face the second sub-chip CH2. A third device isolation part ST3 may be disposed on the front side SB3_F of the third substrate SB3 so as to define active regions for the transfer transistors T1 to T8 (FIG. 4).

Transfer gate electrodes TG and floating diffusion regions FD may be arranged on the front side SB3_F of the third substrate SB3. The front side SB3_F of the third substrate SB3 may be covered with a third interlayer insulating layer IL3. Third contact plugs CT3, third lines IT3, and the like may be arranged in the third interlayer insulating layer IL3. The floating diffusion regions FD of the third sub-chip CH3 may be connected to source follower gate electrodes SF of source follower transistors SX of the second sub-chip CH2. A gate electrode GE of the third sub-chip CH3 may be substituted with a gate electrode of transistors of the second sub-chip CH2.

A lower surface of the third interlayer insulating layer IL3 may be in contact with an upper surface of the second rear insulating film BL2 of the second sub-chip CH2. Fourth conductive pads CP4 may be arranged at a lower end of the third interlayer insulating layer IL3. The fourth conductive pads CP4 may be in contact with the third conductive pads CP3, respectively. There may be no boundary surface between the fourth conductive pads CP4 and the third conductive pads CP3 that are respectively in contact with the fourth conductive pads CP4, and the third and fourth conductive pads CP3 and CP4 corresponding to each other may be integrated.

A rear side SB3_B of the third substrate SB3 may be covered with a third rear insulating film FL. The third rear insulating film FL may include at least one of a fixed charge film, an anti-reflective film, a planarization film, or a protective film. A grid pattern WG, color filters CF1 and CF2, and microlenses ML may be arranged on the third rear insulating film FL in the pixel array region APS. A first optical black pattern BT, a second optical black pattern CFB, a lens residual layer MLR, and the like may be sequentially arranged on the third rear insulating film FL in the edge region ER. The first optical black pattern BT may have the same material and the same thickness as the grid pattern WG. The second optical black pattern CFB may include a blue color filter. The lens residual layer MLR may have the same material as the microlenses ML. Other structures may be the same as/similar to those described above.

Positions of the conductive pads CP1 to CP4 and a through via TV may be various without being limited to those of FIG. 21. An arrangement of the transfer transistors T1 to T8 and driving transistors RX, DCX1, DCX2, S1, S2, and SE may be various without being limited to that of FIG. 21. A pre-charge transistor, a sampling transistor, a capacitor, and/or the like that are/is not illustrated in FIG. 4 may be disposed in at least one of the first sub-chip CH1 or the second sub-chip CH2.

According to various embodiments, a floating diffusion region and a source follower gate electrode may be electrically connected to each other by a buried line. The buried line may be disposed in an upper portion of a substrate and extend along a isolation structure. A source follower contact may be disposed on the source follower gate electrode, and the source follower contact may be electrically connected to the floating diffusion region through the buried line. Accordingly, a contact directly connected to the floating diffusion region may be omitted, and thus junction leakage which occurs between the floating diffusion region and the contact may be prevented/reduced. In addition, since the line is buried in the substrate, a degree of freedom in designing line arrangement may be increased.

In some embodiments, a ground region may be formed on the buried line. Accordingly, a gate electrode of an existing dummy transistor of a pixel region may be used as a gate electrode of a driving transistor. As a result, electrical characteristics of an image sensor may be improved.

Although various embodiments have been described with reference to the accompanying drawings, those of ordinary skill in the art will easily understand that various additional embodiments consistent with the present disclosure can be carried out in other specific forms without changing the technical concept or essential features. Therefore, the above embodiments should be considered illustrative and should not be construed as limiting. The embodiments of FIGS. 1 to 10B may be combined with each other. All such modifications, changes, and combinations are intended to be included within the scope of the appended claims.

What is claimed is:

1. An image sensor comprising:
a substrate;
a pixel region defined by an isolation structure in the substrate;
a first floating diffusion region on the pixel region;
a source follower gate electrode on the substrate; and
a first buried line on the isolation structure,
wherein the first buried line electrically connects the first floating diffusion region to the source follower gate electrode,
wherein the first buried line is disposed in the substrate, and
wherein the first buried line includes:
a first line portion extending from the first floating diffusion region in a first direction, and
a second line portion extending from the source follower gate electrode in a second direction that intersects the first direction.

2. The image sensor of claim 1, further comprising a second floating diffusion region spaced apart from the first floating diffusion region,
wherein the first buried line electrically connects the first floating diffusion region to the second floating diffusion region.

3. The image sensor of claim 1, wherein a level of an upper surface of the first buried line is lower than a level of an upper surface of the source follower gate electrode.

4. The image sensor of claim 1, wherein the first buried line comprises a same material as a material of the first floating diffusion region.

5. The image sensor of claim 1, wherein the image sensor comprises a plurality of the pixel region, and
wherein the plurality of the pixel regions share the first floating diffusion region.

6. The image sensor of claim 1, further comprising a first source follower contact on the source follower gate electrode,
wherein the first source follower contact is in contact with each of the source follower gate electrode and the first buried line.

7. The image sensor of claim 6, wherein the first floating diffusion region is electrically connected to the first source follower contact through the first buried line.

8. The image sensor of claim 6, wherein the first source follower contact comprises a first contact portion and a second contact portion on the first contact portion,
the first contact portion is in direct contact with the first buried line,
the second contact portion is in direct contact with the source follower gate electrode, and
a maximum width of the first contact portion is smaller than a minimum width of the second contact portion.

9. The image sensor of claim 8, wherein the first contact portion comprises a first sidewall adjacent to the source follower gate electrode,
the second contact portion comprises a second sidewall adjacent to the source follower gate electrode,
the first sidewall is offset from the second sidewall in the second direction, and
the first sidewall is spaced apart from the source follower gate electrode in the second direction.

10. The image sensor of claim 1, further comprising a first ground region on the first buried line,
wherein the first ground region is doped with an impurity of a different conductive type from an impurity of the first floating diffusion region.

11. An image sensor comprising:
a substrate;
a pixel region defined by an isolation structure in the substrate;
a first floating diffusion region on the pixel region;
a source follower gate electrode on the substrate;
a first buried line on the isolation structure; and
a first source follower contact on the source follower gate electrode,
wherein the first buried line electrically connects the first floating diffusion region to the source follower gate electrode, and
the first source follower contact is in contact with each of the source follower gate electrode and the first buried line.

12. The image sensor of claim 11, wherein the first floating diffusion region is electrically connected to the first source follower contact through the first buried line.

13. The image sensor of claim 11, wherein the first source follower contact comprises a first contact portion and a second contact portion on the first contact portion,
the first contact portion is in direct contact with the first buried line,
the second contact portion is in direct contact with the source follower gate electrode, and
a maximum width of the first contact portion is smaller than a minimum width of the second contact portion.

14. The image sensor of claim 13, wherein the first contact portion comprises a first sidewall adjacent to the source follower gate electrode,
the second contact portion comprises a second sidewall adjacent to the source follower gate electrode,
the first sidewall is offset from the second sidewall in a direction parallel to an upper surface of the substrate, and
the first sidewall is spaced apart from the source follower gate electrode.

15. The image sensor of claim 14, wherein the second contact portion further comprises a connection outer wall that connects the first sidewall and the second sidewall,
the connection outer wall extends in a first direction in which the upper surface of the substrate extends, and
at least a portion of the connection outer wall is in contact with the source follower gate electrode.

16. A method for manufacturing an image sensor, the method comprising:
forming a pixel region defined by an isolation structure on a substrate;
forming a first floating diffusion region and a first buried line in the substrate;
forming, on the pixel region, a source follower gate electrode which electrically connects the first floating diffusion region to the source follower gate electrode; and
forming a first source follower contact on the source follower gate electrode,
wherein forming the first floating diffusion region and the first buried line includes:
forming a first etched portion by etching an upper portion of the substrate and an upper portion of the isolation structure, and
filling the first etched portion with a semiconductor material.

17. The method of claim 16, wherein forming the first source follower contact comprises:
forming a first interlayer insulating layer covering the source follower gate electrode and the first buried line; and
forming a first contact hole in the first interlayer insulating layer by performing a patterning process,
wherein the first contact hole exposes at least a portion of the source follower gate electrode and at least a portion of the first buried line.

18. The method of claim 17, wherein a level of an exposed upper surface of the source follower gate electrode is higher than a level of a bottom surface of the first contact hole.

19. The method of claim 16, wherein the first etched portion comprises a first recess that exposes the substrate and a second recess that exposes the isolation structure,
the second recess includes:
a first portion extending from the first recess in a first direction; and
a second portion extending from the first portion in a second direction that intersects the first direction.

20. The method of claim 16, further comprising forming a second floating diffusion region spaced apart from the first floating diffusion region,
wherein the first buried line electrically connects the first floating diffusion region to the second floating diffusion region.
